(19) United States
(12) Patent Application Publication
(10) Pub. No.: US 2026/0080910 A1
(43) Pub. Date: Mar. 19, 2026

(54) SEMICONDUCTOR STORAGE DEVICE AND METHOD OF MANUFACTURING THE SAME

(71) Applicant: Kioxia Corporation, Tokyo (JP)

(72) Inventors: Masaki TSUJI, Yokkaichi Mie (JP); Kenta YAMADA, Nagoya Aichi (JP)

(73) Assignee: Kioxia Corporation, Tokyo (JP)

(21) Appl. No.: 19/070,132

(22) Filed: Mar. 4, 2025

(30) Foreign Application Priority Data
Sep. 13, 2024 (JP) 2024-159369

(51) Int. Cl. G11C 5/06; G11C 16/04; H10B 41/10; H10B 41/27; H10B 41/35; H10B 43/10; H10B 43/27; H10B 43/35

(52) U.S. Cl. CPC G11C 5/063; G11C 16/0483; H10B 41/10; H10B 41/27; H10B 41/35; H10B 43/10; H10B 43/27; H10B 43/35

(57) ABSTRACT

A semiconductor storage device according to one embodiment has a first multi-layered body, a second multi-layered body, a source line, a first columnar part, a second columnar part, a first bit line, and a second bit line. The source line is between the first multi-layered body and the second multi-layered body in a first direction. The first columnar part extends in the first direction within the first multi-layered body. The second columnar part extends in the first direction within the second multi-layered body. The first bit line is on a side of the first multi-layered body opposite to the source line.

The second bit line is on a side of the second multi-layered body opposite to the source line.

### CROSS-REFERENCE TO RELATED APPLICATION

Priority is claimed on Japanese Patent Application No. 2024-159369, filed Sep. 13, 2024, the content of which is incorporated herein by reference.

### FIELD

Embodiments of the present invention relates to a semiconductor storage device and a method of manufacturing the semiconductor storage device.

### BACKGROUND ART

NAND-type flash memories including memory cells disposed three-dimensionally are known.

### BRIEF DESCRIPTION OF THE DRAWINGS

FIG. 1 is a block diagram showing a part of a semiconductor storage device according to a first embodiment.

FIG. 2 is a diagram showing an equivalent circuit of a part of a memory cell array according to the first embodiment.

FIG. 3 is a diagram showing the semiconductor storage device according to the first embodiment.

FIG. 4 is a diagram showing region division of the memory cell array according to the first embodiment.

FIG. 5 is a cross-sectional view showing the semiconductor storage device shown in FIG. 4 taken along line F5-F5.

FIG. 6 is a cross-sectional view showing the semiconductor storage device shown in FIG. 4 taken along line F6-F6.

FIG. 7 is an enlarged view showing a region surrounded by line F7 in the structure shown in FIG. 4.

FIG. 8 is an enlarged view showing a region surrounded by line F8 in the structure shown in FIG. 7.

FIG. 9 is a cross-sectional view showing a memory pillar according to the first embodiment.

FIG. 10 is a cross-sectional view showing the structure shown in FIG. 9 taken along line F10-F10.

FIG. 11 is a cross-sectional view showing a schematic structure of the semiconductor storage device according to the first embodiment.

FIG. 12 is a cross-sectional view showing a method of manufacturing the semiconductor storage device according to the first embodiment.

FIG. 13 is a cross-sectional view showing a method of manufacturing the semiconductor storage device according to the first embodiment.

FIG. 14 is a cross-sectional view showing a method of manufacturing the semiconductor storage device according to the first embodiment.

FIG. 15 is a cross-sectional view showing a method of manufacturing the semiconductor storage device according to the first embodiment.

FIG. 16 is a cross-sectional view showing a method of manufacturing the semiconductor storage device according to the first embodiment.

FIG. 17 is a cross-sectional view showing a method of manufacturing the semiconductor storage device according to the first embodiment.

FIG. 18 is a cross-sectional view showing a method of manufacturing the semiconductor storage device according to the first embodiment.

FIG. 19 is a cross-sectional view showing a method of manufacturing the semiconductor storage device according to the first embodiment.

FIG. 20 is a cross-sectional view showing a method of manufacturing the semiconductor storage device according to the first embodiment.

FIG. 21 is a cross-sectional view showing a method of manufacturing the semiconductor storage device according to the first embodiment.

FIG. 22 is a cross-sectional view showing a method of manufacturing the semiconductor storage device according to the first embodiment.

FIG. 23 is a cross-sectional view showing a method of manufacturing the semiconductor storage device according to the first embodiment.

FIG. 24 is a cross-sectional view showing a method of manufacturing the semiconductor storage device according to the first embodiment.

FIG. 25 is a cross-sectional view showing a method of manufacturing the semiconductor storage device according to the first embodiment.

FIG. 26 is a cross-sectional view showing a method of manufacturing the semiconductor storage device according to the first embodiment.

FIG. 27 is a cross-sectional view showing a method of manufacturing the semiconductor storage device according to the first embodiment.

FIG. 28 is a cross-sectional view showing a method of manufacturing the semiconductor storage device according to the first embodiment.

FIG. 29 is a cross-sectional view showing a method of manufacturing the semiconductor storage device according to the first embodiment.

FIG. 30 is a cross-sectional view showing a method of manufacturing the semiconductor storage device according to the first embodiment.

FIG. 31 is a cross-sectional view showing a method of manufacturing the semiconductor storage device according to the first embodiment.

FIG. 32 is a cross-sectional view showing a method of manufacturing the semiconductor storage device according to the first embodiment.

FIG. 33 is a cross-sectional view showing a method of manufacturing the semiconductor storage device according to the first embodiment.

FIG. 34 is a cross-sectional view showing a method of manufacturing the semiconductor storage device according to the first embodiment.

FIG. 35 is a cross-sectional view showing a method of manufacturing the semiconductor storage device according to the first embodiment.

FIG. 36 is a cross-sectional view showing a method of manufacturing the semiconductor storage device according to the first embodiment.

FIG. 37 is a cross-sectional view showing a method of manufacturing the semiconductor storage device according to the first embodiment.

FIG. 38 is a cross-sectional view showing a method of manufacturing the semiconductor storage device according to the first embodiment.

FIG. 39 is a cross-sectional view showing a method of manufacturing the semiconductor storage device according to the first embodiment.

FIG. 40 is a cross-sectional view showing a method of manufacturing the semiconductor storage device according to the first embodiment.

FIG. 41 is a cross-sectional view showing a method of manufacturing the semiconductor storage device according to the first embodiment.

FIG. 42 is a cross-sectional view showing a method of manufacturing the semiconductor storage device according to the first embodiment.

FIG. 43 is a cross-sectional view showing a method of manufacturing the semiconductor storage device according to the first embodiment.

FIG. 44 is a cross-sectional view showing a method of manufacturing the semiconductor storage device according to the first embodiment.

FIG. 45 is a cross-sectional view showing a method of manufacturing the semiconductor storage device according to the first embodiment.

FIG. 46 is a cross-sectional view showing a method of manufacturing the semiconductor storage device according to the first embodiment.

FIG. 47 is a cross-sectional view showing a method of manufacturing the semiconductor storage device according to the first embodiment.

FIG. 48 is a cross-sectional view showing a part of a semiconductor storage device according to a second embodiment.

FIG. 49 is a cross-sectional view showing a memory pillar according to the second embodiment.

FIG. 50 is a cross-sectional view showing the structure shown in FIG. 48 taken along line F50-F50.

FIG. 51 is a cross-sectional view showing a method of manufacturing the semiconductor storage device according to the second embodiment.

FIG. 52 is a cross-sectional view showing a method of manufacturing the semiconductor storage device according to the second embodiment.

FIG. 53 is a cross-sectional view showing a method of manufacturing the semiconductor storage device according to the second embodiment.

FIG. 54 is a cross-sectional view showing a method of manufacturing the semiconductor storage device according to the second embodiment.

FIG. 55 is a cross-sectional view showing a method of manufacturing the semiconductor storage device according to the second embodiment.

FIG. 56 is a cross-sectional view showing a method of manufacturing the semiconductor storage device according to the second embodiment.

### DETAILED DESCRIPTION

A semiconductor storage device according to an embodiment includes a first multi-layered body, a second multi-layered body, a source line, a first columnar part, a second columnar part, a first bit line, and a second bit line. The first multi-layered body includes a plurality of first gate electrode layers and a plurality of first insulating layers. The plurality of first gate electrode layers and the plurality of first insulating layers are alternately stacked one by one in a first direction. The second multi-layered body is on a first side of the first multi-layered body in the first direction. The second multi-layered body includes a plurality of second gate electrode layers and a plurality of second insulating layers. The plurality of second gate electrode layers and the plurality of second insulating layers are alternately stacked one by one in the first direction. The source line is between the first multi-layered body and the second multi-layered body in the first direction. The source line extends in a second direction intersecting the first direction. The first columnar part extends in the first direction within the first multi-layered body. The first columnar part includes a first memory film and a first semiconductor film. The first memory film includes a charge storage part. The second columnar part extends in the first direction within the second multi-layered body. The second columnar part includes a second memory film and a second semiconductor film. The second memory film includes a charge storage part. The first bit line is on a side of the first multi-layered body opposite to the source line. The first bit line is electrically connected to the first columnar part. The second bit line is on a side of the second multi-layered body opposite to the source line. The second bit line is electrically connected to the second columnar part.

Hereinafter, a semiconductor storage device and a method of manufacturing the semiconductor storage device according to an embodiment will be described with reference to the drawings. In the following description, components having the same or similar functions are denoted by the same reference numerals. Repeated description of those components may be omitted. In the following description, the reference numerals or letters at the end for distinguishing between them may be omitted when they are not required to be distinguished from each other. In the drawings described below, the illustration of components that are not related to the description may be omitted.

In this application, the terms are defined as follows. “Parallel”, “orthogonal”, or “same” may include the cases of “substantially parallel”, “substantially orthogonal”, or “substantially the same”, respectively. “Connection” is not limited to mechanical connection, and may include electrical connection. In other words, “connection” is not limited to a case where a plurality of elements are directly connected, and may include a case where a plurality of elements are connected with another element interposed therebetween. “Adjacent” is not limited to a case where a plurality of elements are in contact with each other, and may include a case where a plurality of elements are adjacent to each other with another element interposed therebetween.

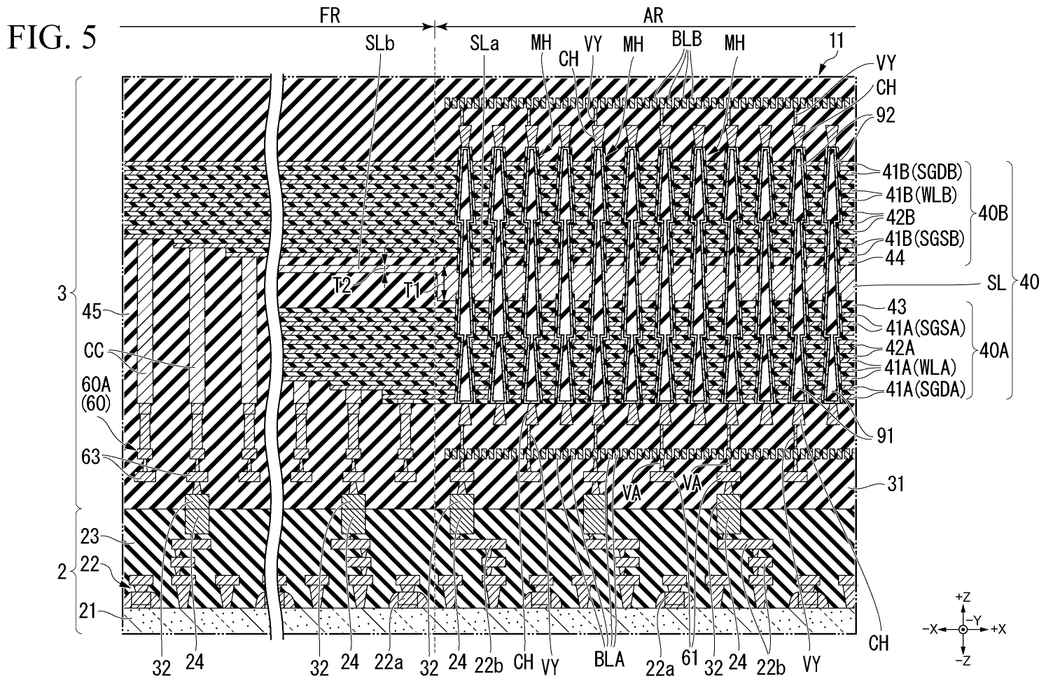

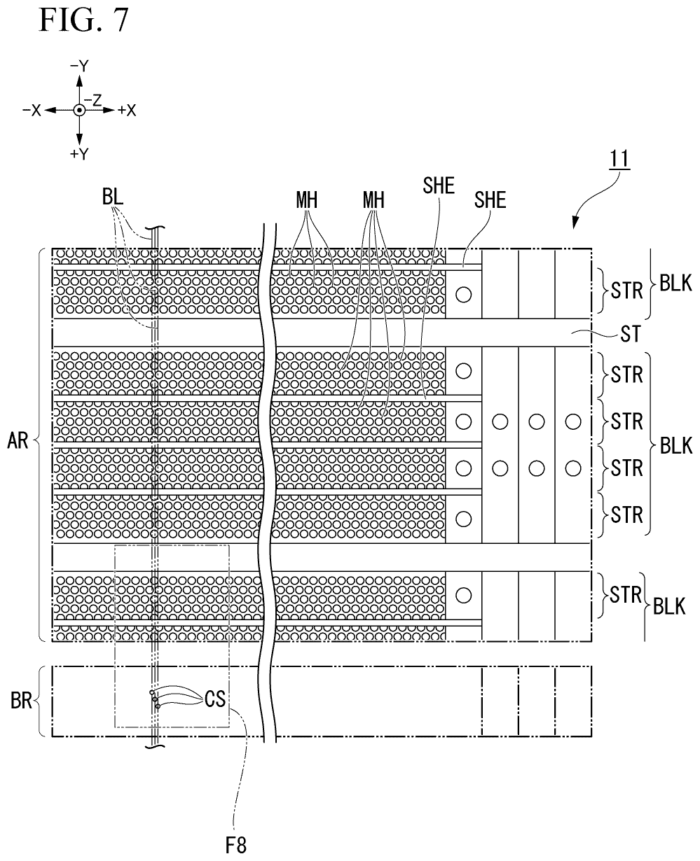

A +X direction, a −X direction, a +Y direction, a −Y direction, a +Z direction, and a −Z direction are defined as follows. The +X direction is a direction in which a word line WL, which will be described later, extends (refer to FIG. 5). The −X direction is a direction opposite to the +X direction. When the +X direction and the −X direction are not distinguished from each other, they are simply referred to as an “X direction”. The +Y direction is a direction intersecting (for example, is perpendicular to) the X direction. The +Y direction is a direction in which the bit line BL extends (refer to FIG. 7). The −Y direction is a direction opposite to the +Y direction. When the +Y direction and the −Y direction are not distinguished from each other, they are simply referred to as a “Y direction”. The +Z direction is a direction intersecting (for example, is perpendicular to) the X direction and the Y direction. The +Z direction is a direction from a first multi-layered body 40A to a second multi-layered body 40B which will be described later (refer to FIG. 5). The −Z direction is a direction opposite to the +Z direction. When the +Z direction and the −Z direction are not distinguished from each other, they are simply referred to as a “Z direction”. In this application, a side in the +Z direction may be referred to as “upper”, a side in the −Z direction may be referred to as “lower”. Furthermore, in this application, a position in the Z direction may be referred to as “height”. However, these expressions are used for convenience of description and do not specify the direction of gravity. The Z direction is an example of a “first direction”. The side in the +Z direction is an example of a “first side”. The side in the −Z direction is an example of a “second side”. The X direction is an example of a “second direction”.

### First Embodiment

### A1. Configuration of Semiconductor Storage Device

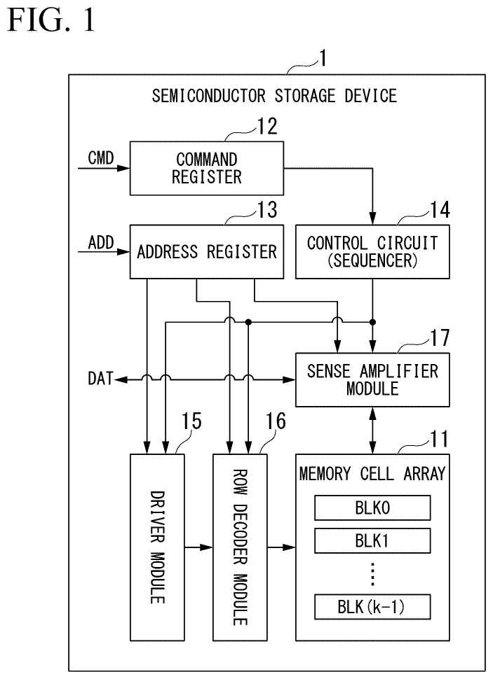

FIG. 1 is a block diagram showing a part of a semiconductor storage device 1 according to a first embodiment. The semiconductor storage device 1 is, for example, a non-volatile semiconductor storage device. The semiconductor storage device 1 is a NAND-type flash memory. The semiconductor storage device 1 can be connected to an external host device. The semiconductor storage device 1 is used as a storage space for a host device. The semiconductor storage device 1 includes, for example, a memory cell array 11, a command register 12, an address register 13, a control circuit (sequencer) 14, a driver module 15, a row decoder module 16, and a sense amplifier module 17.

The memory cell array 11 includes a plurality of blocks BLK0 to BLK(k-1) (k is an integer of 1 or more). The block BLK is a collection of memory cell transistors. The block BLK is used as a data erase unit. The memory cell array 11 is provided with a plurality of bit lines and a plurality of word lines. Each memory cell transistor is associated with one bit line and one word line.

The command register 12 stores a command CMD received by the semiconductor storage device 1 from the host device. The address register 13 stores address information ADD received by the semiconductor storage device 1 from the host device. The address information ADD is used to select the block BLK, the word line, and the bit line. The control circuit 14 controls various operations of the semiconductor storage device 1. For example, the control circuit 14 executes a data write operation, a read operation, or an erase operation based on the command CMD stored in the command register 12.

The driver module 15 includes a voltage generation circuit and generates voltages used in various operations of the semiconductor storage device 1. The row decoder module 16 transfers a voltage applied to a signal line corresponding to a selected word line to a selected word line. The sense amplifier module 17 applies a desired voltage to each bit line in a write operation. In a read operation, the sense amplifier module 17 determines data stored in each memory cell transistor based on the voltage of each bit line, and transfers a determination result to the host device as read data DAT. The sense amplifier module 17 is an example of a “circuit”.

### A2. Electrical Configuration of Memory Cell Array

### A2.1 Configuration Related to One Block BLK

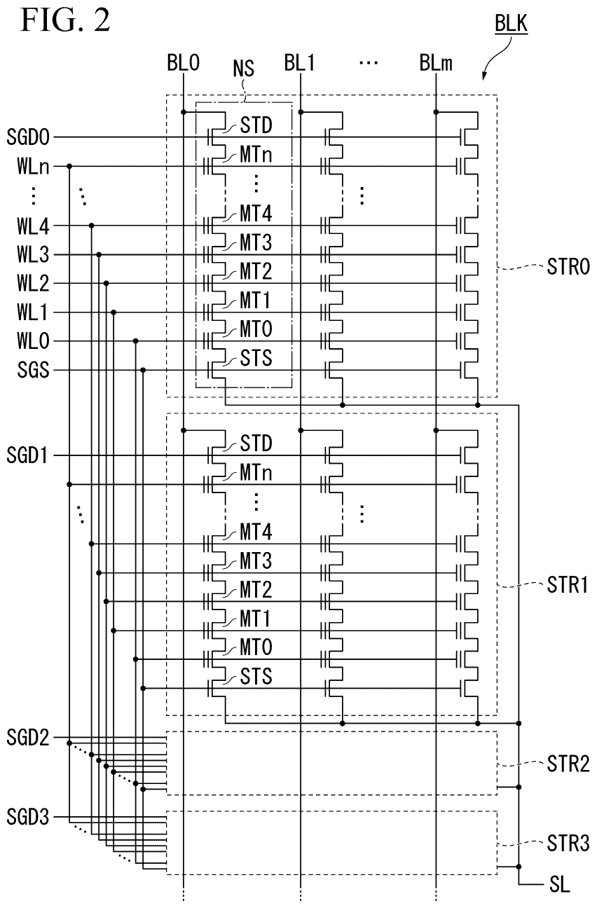

FIG. 2 is a diagram showing an equivalent circuit of a part of the memory cell array 11. FIG. 2 shows one block BLK included in the memory cell array 11. The block BLK includes a plurality of strings STR (for example, four strings STR0 to STR3).

Each string STR includes a plurality of NAND strings NS, respectively associated with bit lines BL0 to BLm (m is an integer of 1 or more). Each NAND string NS includes a plurality of memory cell transistors MT0 to MTn (n is an integer of 1 or more), one or more drain-side select transistors STD, and one or more source-side select transistors STS.

In each NAND string NS, the memory cell transistors MT0 to MTn are connected in series. Each memory cell transistor MT includes a control gate and a charge storage part. The control gate of the memory cell transistor MT is connected to any one of the word lines WL0 to WLn. In each memory cell transistor MT, charge is stored in the charge storage part in accordance with a voltage applied to the control gate via the word line WL. Therefore, each memory cell transistor MT stores data non-volatilely.

A drain of the drain-side select transistor STD is connected to the bit line BL corresponding to the NAND string NS. A source of the drain-side select transistor STD is connected to one end of each of the memory cell transistors MT0 to MTn connected in series. The control gate of the drain-side select transistor STD is connected to any one of drain-side select gate lines SGD0 to SGD3. The drain-side select transistor STD is electrically connected to the row decoder module 16 via the drain-side select gate line SGD. The drain-side select transistor STD connects the NAND string NS and the bit line BL when a predetermined voltage is applied to the corresponding drain-side select gate line SGD.

A drain of the source-side selection transistor STS is connected to the other end of each of the memory cell transistors MT0 to MTn connected in series. A source of the source-side selection transistor STS is connected to the source line SL. The control gate of the source-side selection transistor STS is connected to a source-side select gate line SGS. The source-side selection transistor STS connects the NAND string NS to the source line SL when a predetermined voltage is applied to the source-side select gate line SGS.

In the same block BLK, the control gates of the memory cell transistors MT0 to MTn are connected in common to the corresponding word lines WL0 to WLn. In the same string STR, the control gates of the drain-side select transistors STD are connected in common to the corresponding drain-side select gate line SGD. The control gates of the source-side select transistors STS are connected in common to the source-side select gate line SGS. In the memory cell array 11, the bit line BL is shared by the NAND strings NS that are assigned the same column address in a plurality of strings STR.

### A2.2 Configuration Related to Plurality of Blocks BLK

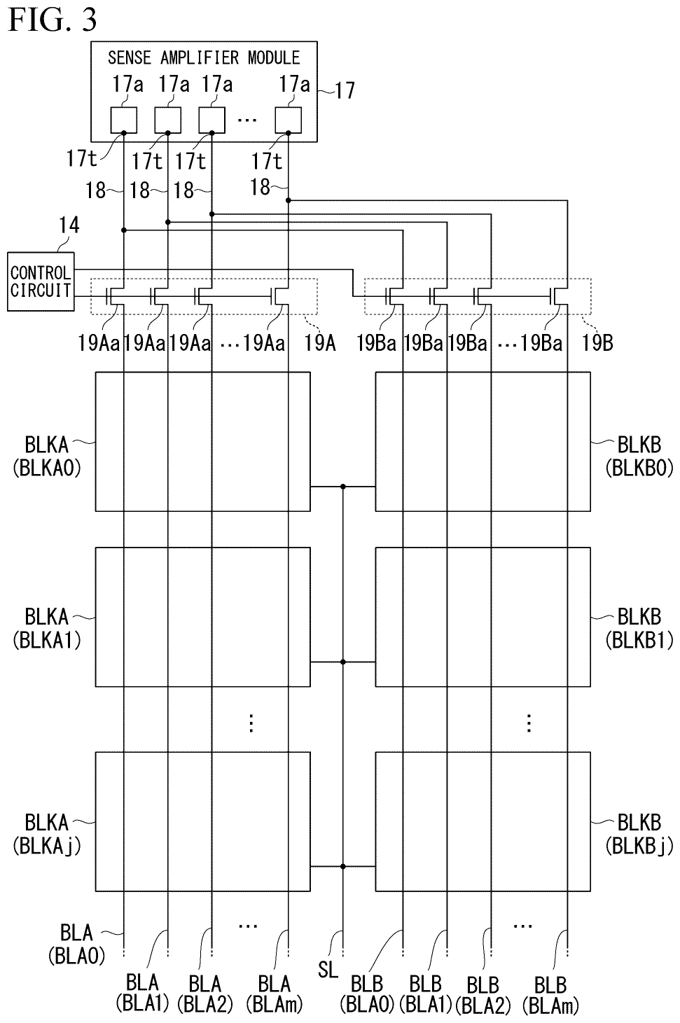

FIG. 3 is a diagram showing the semiconductor storage device 1. FIG. 3 shows a plurality of blocks BLK included in the memory cell array 11. The memory cell array 11 includes a plurality of blocks BLK. The plurality of blocks BLK include a plurality of blocks BLKA (a plurality of blocks BLKA0 to BLKAj (j is an integer of 1 or more)) and a plurality of blocks BLKB (a plurality of blocks BLKB0 to BLKBj (j is an integer of 1 or more)). The blocks BLKA are blocks BLK included in a first multi-layered body 40A (refer to FIG. 5) to be described later. The blocks BLKB are blocks BLK included in a second multi-layered body 40B (refer to FIG. 5) to be described later.

In this embodiment, the memory cell array 11 includes a plurality of bit lines BL. The plurality of bit lines BL include a plurality of bit lines BLA (bit lines BLA0 to BLAm (m is an integer of 1 or more)) and a plurality of bit lines BLB (bit lines BLB0 to BLBm (m is an integer of 1 or more)).

The plurality of bit lines BLA are provided corresponding to a plurality of blocks BLKA. For example, the plurality of bit lines BLA are provided in common to a plurality of blocks BLKA. For convenience of description, the bit line BLA may be referred to as a “lower bit line BLA” below. The lower bit line BLA is an example of a “first bit line.”

The plurality of bit lines BLB are provided corresponding to the plurality of blocks BLKB. For example, the plurality of bit lines BLB are provided in common to the plurality of blocks BLKB. For convenience of description, the bit line BLB may be referred to as an “upper bit line BLB” below. The upper bit line BLB is an example of a “second bit line.”

The sense amplifier module 17 includes a plurality of sense amplifier units 17a. The plurality of sense amplifier units 17a are provided corresponding to a plurality of bit lines BL. Each sense amplifier unit 17a is, for example, a circuit controlled by a signal from the control circuit 14. For example, the sense amplifier unit 17a includes a latch circuit electrically connected to the corresponding bit line BL. The sense amplifier unit 17a applies a voltage to the corresponding bit line BL based on a signal from the control circuit 14. Each sense amplifier unit 17a includes a terminal 17t to which an electrical connection line 18 to be described below is connected. The terminal 17t is an example of a “first terminal”.

In this embodiment, the memory cell array 11 includes a plurality of electrical connection lines 18 and a switching circuit 19 in addition to the above-described configuration.

The plurality of electrical connection lines 18 are provided between the plurality of sense amplifier units 17a and the plurality of bit lines BL. The plurality of electrical connection lines 18 are connection lines. The connection lines electrically connect the plurality of sense amplifier units 17a and the plurality of bit lines BL. The plurality of electrical connection lines 18 are provided in a one-to-one relationship with the plurality of sense amplifier units 17a. For example, the plurality of electrical connection lines 18 are electrically connected in a one-to-one relationship to the terminals 17t of the plurality of sense amplifier units 17a.

The switching circuit 19 is a circuit configured to switch at least between a first state and a second state. The first state is a state in which the terminals 17t of the plurality of sense amplifier units 17a are electrically connected to the plurality of lower bit lines BLA in a one-to-one relationship. The second state is a state in which the terminals 17t of the plurality of sense amplifier units 17a are electrically connected to the plurality of upper bit lines BLB in a one-to-one relationship. The switching circuit 19 includes, for example, a switching circuit 19A and a switching circuit 19B.

The switching circuit 19A is provided between the plurality of electrical connection lines 18 and the plurality of lower bit lines BLA. The switching circuit 19A includes a plurality of switching elements 19Aa. The plurality of switching elements 19Aa are configured to electrically connect the plurality of electrical connection lines 18 and the plurality of lower bit lines BLA in a one-to-one relationship. The plurality of switching elements 19Aa are controlled, for example, by a common signal from the control circuit 14 for the plurality of switching elements 19Aa. The switching circuit 19A can switch between a first state and a second state. The first state is a state in which the plurality of electrical connection lines 18 and the plurality of lower bit lines BLA are electrically connected. The second state is a state in which the plurality of electrical connection lines 18 and the plurality of lower bit lines BLA are electrically cut off.

The switching circuit 19B is provided between the plurality of electrical connection lines 18 and the plurality of upper bit lines BLB. The switching circuit 19B includes a plurality of switching elements 19Ba. The plurality of switching elements 19Ba are configured to electrically connect the plurality of electrical connection lines 18 and the plurality of upper bit lines BLB in a one-to-one relationship. The plurality of switching elements 19Ba are controlled, for example, by a common signal from the control circuit 14 for the plurality of switching elements 19Ba. The switching circuit 19B can switch between a first state and a second state. The first state is a state in which the plurality of electrical connection lines 18 and the plurality of upper bit lines BLB are electrically connected. The second state is a state in which the plurality of electrical connection lines 18 and the plurality of upper bit lines BLB are electrically cut off.

### A3. Structure of Semiconductor Storage Device

Next, the structure of the semiconductor storage device 1 will be described.

### A3.1 Region Division of Memory Cell Array First, region division of the memory cell array 11 will be described.

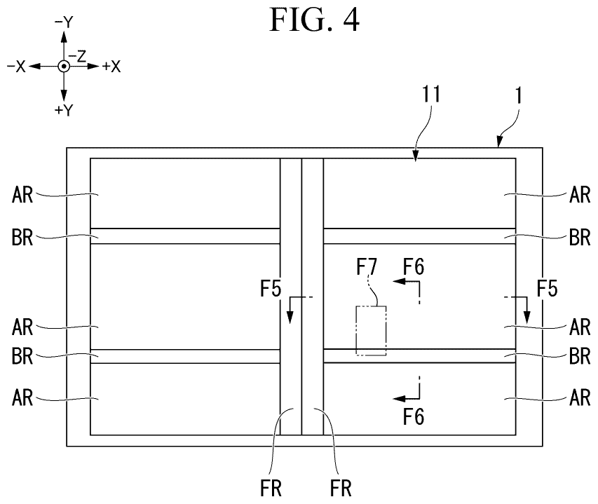

FIG. 4 is a diagram showing the region division of the memory cell array 11. The memory cell array 11 includes, for example, a plurality of array regions AR, a plurality of hook-up regions FR, and a plurality of bit line tap regions BR.

The array region AR is provided with a plurality of memory pillars MH, which will be described later. The array region AR is a region capable of storing data. The hook-up region FR is a region in which a plurality of contacts CC, which will be described later, are provided. The hook-up region FR is a region in which a plurality of gate electrode layers 41, which will be described later, and a wiring part 60 are electrically connected. In the example shown in FIG. 4, the hook-up region FR is provided on one side of the array region AR in the X direction. However, the hook-up region FR may be provided on both sides of the array region AR in the X direction.

The bit line tap region BR is provided with a plurality of contacts CS, which will be described later. The bit line tap region BR is a region in which the switching circuit 19 (or the sense amplifier module 17) and a plurality of upper bit lines BLB are electrically connected. The bit line tap region BR may also be referred to as a “bit line connection region”. The bit line tap region BR is disposed between two array regions AR adjacent to each other in the Y direction. The bit line tap region BR extends in the X direction.

### A3.2 Bonding Structure

Next, a bonding structure of the semiconductor storage device 1 will be described.

FIG. 5 is a cross-sectional view showing the semiconductor storage device 1 shown in FIG. 4 taken along line F5-F5. The semiconductor storage device 1 includes, for example, a first chip 2 and a second chip 3. The second chip 3 is a chip bonded to the first chip 2.

### First Chip

The first chip 2 is a circuit chip including a peripheral circuit. The first chip 2 includes, for example, a semiconductor substrate 21, a peripheral circuit 22, an insulating part 23, and a plurality of pads 24.

The semiconductor substrate 21 is, for example, a substrate serving as the base of the first chip 2. At least a part of the semiconductor substrate 21 is plate-shaped in the X direction and the Y direction. The semiconductor substrate 21 is formed of a semiconductor material such as silicon.

The peripheral circuit 22 is a circuit configured to operate the memory cell array 11 mentioned above. The peripheral circuit 22 includes a plurality of transistors 22a and a plurality of electrical connection lines 22b. The peripheral circuit 22 includes one or more of the command register 12, the address register 13, the control circuit 14, the driver module 15, the row decoder module 16, the sense amplifier module 17, the plurality of electrical connection lines 18, and the switching circuit 19 mentioned above. For example, each of the switching elements 19Aa and 19Ba of the switching circuit 19 is formed by the transistors 22a provided on the semiconductor substrate 21. The insulating part 23 covers the peripheral circuit 22. The plurality of pads 24 are provided on the surface of the insulating part 23. The pads 24 are electrically connected to the peripheral circuit 22.

### Second Chip

The second chip 3 is an array chip including the memory cell array 11. The second chip 3 includes, for example, the memory cell array 11, an insulating part 31, and a plurality of pads 32. Here, the insulating part 31 and the plurality of pads 32 are described, and the memory cell array 11 will be described later.

The insulating part 31 covers the memory cell array 11 from the side in the −Z direction. The plurality of pads 32 are provided on the surface of the insulating part 31. The pads 32 are electrically connected to an electrical connection line (for example, electrical connection lines 61, 62, 63, 64) included in the wiring part 60 of the memory cell array 11 to be described later. In this embodiment, the plurality of pads 24 of the first chip 2 and the plurality of pads 32 of the second chip 3 are bonding together to face each other, and thus the first chip 2 and the second chip 3 are integrated.

### A4. Structures of Array Region and Hook-Up Region

Next, structures of the array region AR and the hook-up region FR will be described.

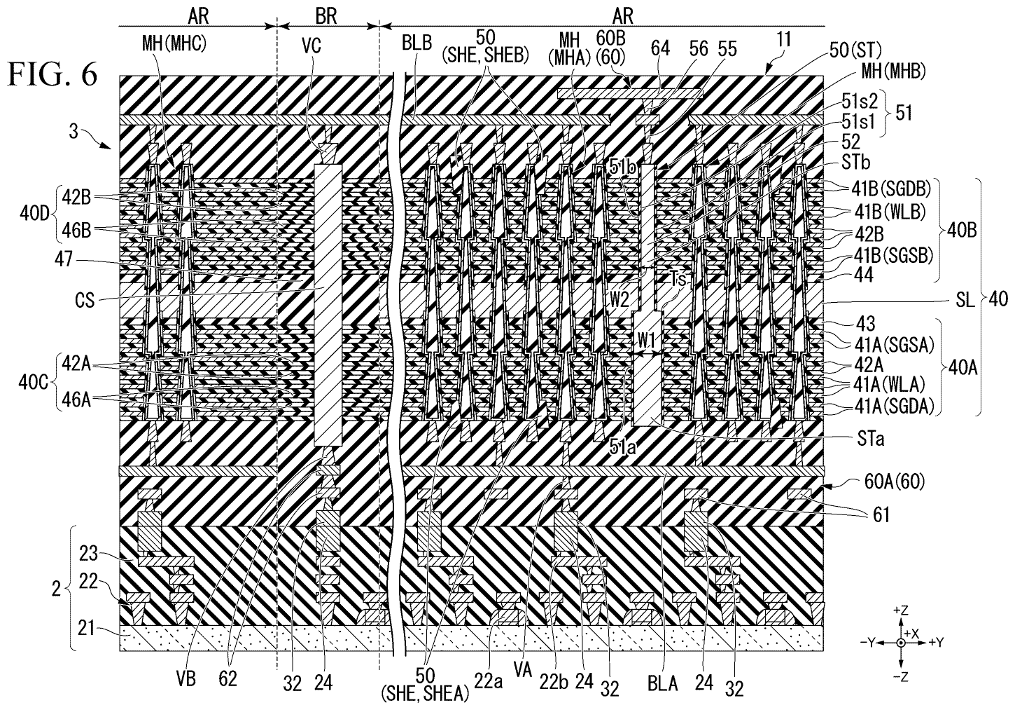

As shown in FIG. 5, the memory cell array 11 includes, for example, a multi-layered body 40, an insulating part 45, a plurality of memory pillars MH, a plurality of lower bit lines BLA, a plurality of upper bit lines BLB, a plurality of contacts CH for the memory pillars, a plurality of contacts VY for the memory pillars, a contact CC for the gate electrode layer, a plurality of separation parts 50 (refer to FIG. 6), and a wiring part 60. The multi-layered body 40 includes a first multi-layered body 40A, a second multi-layered body 40B, and a source line SL. Note that, the memory pillar MH will be described later.

### A4.1 First Multi-Layered Body

The first multi-layered body 40A is a multi-layered body forming a plurality of blocks BLKA mentioned above. The first multi-layered body 40A includes, for example, a plurality of gate electrode layers 41A, a plurality of insulating layers 42A, and an insulating layer 43. The plurality of gate electrode layers 41A and the plurality of insulating layers 42A are alternately stacked one by one in the Z direction.

The gate electrode layer 41A is a conductive layer in the X direction and the Y direction. Each gate electrode layer 41A includes a conductive material (for example, tungsten, molybdenum, or silicon doped with impurities). The gate electrode layer 41A is an example of a “first gate electrode layer”.

Among the plurality of gate electrode layers 41A, one or more (for example, a plurality of) gate electrode layers 41A located on the upper side function as a source-side select gate line SGS (source-side select gate line SGSA) for the block BLKA. The source-side select gate line SGSA is provided in common for lower columnar parts 91 (described later) of a plurality of memory pillars MH arranged in the X direction or the Y direction. The intersection of the source-side select gate line SGSA and a channel layer 72 (described later) of each memory pillar MH functions as the source-side select transistor STS mentioned above.

Among the plurality of gate electrode layers 41A, one or more (for example, a plurality of) gate electrode layers 41A located on the lower side function as a drain-side select gate line SGD (drain-side select gate line SGDA) for the block BLKA. The drain-side select gate line SGDA is provided in common for the lower columnar parts 91 (described later) of the plurality of memory pillars MH arranged in the X direction or the Y direction. The intersection of the drain-side select gate line SGDA and the channel layer 72 (described later) of each memory pillar MH functions as the drain-side select transistor STD mentioned above.

Among the plurality of gate electrode layers 41A, the gate electrode layers 41A provided between the gate electrode layers 41A functioning as the source-side select gate line SGSA and the drain-side select gate line SGDA are the remaining gate electrode layers 41A. At least some of such remaining gate electrode layers 41A function as word lines WL (WLA) for the block BLKA. The word line WL is provided in common for the lower columnar parts 91 (described later) of the plurality of memory pillars MH arranged in the X direction and the Y direction. In this embodiment, the intersection of the word line WL and the channel layer 72 (described later) of each memory pillar MH functions as the memory cell transistor MT mentioned above.

The plurality of gate electrode layers 41A have different lengths in the X direction in the hook-up region FR. For example, regarding the lengths of the plurality of gate electrode layers 41A stacked in the Z direction, the length in the X direction of the gate electrode layer 41A located on the side in the +Z direction is greater than the length in the X direction of the gate electrode layer 41A located on the side in the −Z direction. In other words, the closer the gate electrode layer 41A is located on the side in the +Z direction, the greater the length in the X direction. Therefore, the ends of the plurality of gate electrode layers 41A are disposed in a stepped shape in the hook-up region FR.

The insulating layer 42A is provided between two gate electrode layers 41A adjacent to each other in the Z direction. The insulating layer 42A is an interlayer insulating film. The interlayer insulating film insulates the two gate electrode layers 41A from each other. The insulating layer 42A extends in the X direction and the Y direction. The insulating layer 42A is formed by, for example, a film containing silicon and oxygen (for example, a silicon oxide film). The insulating layer 42A is an example of a “first insulating layer”.

The insulating layer 43 is an insulating layer provided above the gate electrode layer 41A disposed on the uppermost side. In other words, the insulating layer 43 may be referred to as an insulating layer provided above the gate electrode layer which is the uppermost layer. The insulating layer 43 is disposed between the gate electrode layer 41A disposed on the uppermost side and the source line SL. The insulating layer 43 extends in the X direction and the Y direction. The insulating layer 43 is formed by, for example, a film containing silicon and oxygen (for example, a silicon oxide film). For example, the thickness of the insulating layer 43 in the Z direction is greater than the thickness of the insulating layer 42A in the Z direction.

### A4.2 Second Multi-Layered Body

The second multi-layered body 40B is a multi-layered body forming the plurality of blocks BLKB mentioned above. The second multi-layered body 40B is disposed on the upper side (the side in the +Z direction) of the first multi-layered body 40A. The second multi-layered body 40B includes, for example, a plurality of gate electrode layers 41B, a plurality of insulating layers 42B, and an insulating layer 44. The plurality of gate electrode layers 41B and the plurality of insulating layers 42B are alternately stacked one by one in the Z direction.

The gate electrode layer 41B is a conductive layer in the X direction and the Y direction. Each gate electrode layer 41B contains a conductive material (for example, tungsten, molybdenum, or silicon doped with impurities). The gate electrode layer 41B is an example of a “second gate electrode layer”.

Among the plurality of gate electrode layers 41B, one or more (for example, a plurality of) gate electrode layers 41B located on the lower side function as a source-side select gate line SGS (source-side select gate line SGSB) for the block BLKB. The source-side select gate line SGSB is provided in common for the upper columnar parts 92 (described later) of the plurality of memory pillars MH arranged in the X direction or the Y direction. The intersection of the source-side select gate line SGSB and the channel layer 72 (described later) of each memory pillar MH functions as the source-side select transistor STS mentioned above.

Among the plurality of gate electrode layers 41B, one or more (for example, a plurality of) gate electrode layers 41B located on the upper side function as a drain-side select gate line SGD (drain-side select gate line SGDB) for the block BLKB. The drain-side select gate line SGDB is provided in common for the upper columnar parts 92 (described later) of the plurality of memory pillars MH arranged in the X direction or the Y direction. The intersection of the drain-side select gate line SGDB and the channel layer 72 (described later) of each memory pillar MH functions as the drain-side select transistor STD mentioned above.

Among the plurality of gate electrode layers 41B, the gate electrode layers 41B provided between the gate electrode layers 41B functioning as the source-side select gate line SGSB and the drain-side select gate line SGDB are the remaining gate electrode layers 41B. At least some of such gate electrode layers 41B function as word lines WL (WLB) for the block BLKB. The word line WL is provided in common for the upper columnar parts 92 (described later) of the plurality of memory pillars MH arranged in the X direction and the Y direction. In this embodiment, the intersection of the word line WL and the channel layer 72 (described later) of each memory pillar MH functions as the memory cell transistor MT mentioned above.

The plurality of gate electrode layers 41B have different lengths in the X direction in the hook-up region FR. For example, regarding the lengths of the plurality of gate electrode layers 41B stacked in the Z direction, the length in the X direction of the gate electrode layer 41B located on the side in the +Z direction is greater than the length in the X direction of the gate electrode layer 41B located on the side in the −Z direction. In other words, the closer the gate electrode layer 41B is located on the side in the +Z direction, the greater the length in the X direction. Therefore, the ends of the plurality of gate electrode layers 41B are disposed in a stepped shape in the hook-up region FR.

The insulating layer 42B is provided between two gate electrode layers 41B adjacent to each other in the Z direction. The insulating layer 42B is an interlayer insulating film. The interlayer insulating film insulates the two gate electrode layers 41B from each other. The insulating layer 42B extends in the X direction and the Y direction. The insulating layer 42B is formed by, for example, a film containing silicon and oxygen (for example, a silicon oxide film). The insulating layer 42B is an example of a “second insulating layer”.

The insulating layer 44 is an insulating layer provided below the gate electrode layer 41B disposed on the lowermost side. In other words, the insulating layer 44 may be referred to as an insulating layer provided below the gate electrode layer which is the lowermost layer. The insulating layer 44 is disposed between the gate electrode layer 41B disposed on the lowermost side and the source line SL. The insulating layer 44 extends in the X direction and the Y direction. The insulating layer 44 is formed by, for example, a film containing silicon and oxygen (for example, a silicon oxide film). For example, the thickness of the insulating layer 44 in the Z direction is greater than the thickness of the insulating layer 42B in the Z direction.

In one example of the semiconductor storage device 1, the number of gate electrode layers 41A included in the first multi-layered body 40A is different from the number of gate electrode layers 41B included in the second multi-layered body 40B. In this case, the size of the block BLKA included in the first multi-layered body 40A is different from the size of the block BLKB included in the second multi-layered body 40B. This point will be described in detail later. Note that, the number of gate electrode layers 41A included in the first multi-layered body 40A may be the same as the number of gate electrode layers 41B included in the second multi-layered body 40B.

Furthermore, in the following, when the first gate electrode layer 41A and the second gate electrode layer 41B are not distinguished from each other, they may be simply referred to as a “gate electrode layer 41”. When the first insulating layer 42A and the second insulating layer 42B are not distinguished from each other, they may be simply referred to as an “insulating layer 42”.

### A4.3 Source Line

The source line SL is disposed between the first multi-layered body 40A and the second multi-layered body 40B in the Z direction. The source line SL extends in the X direction and the Y direction. The source line SL is a conductive layer or a semiconductor layer in the X direction and the Y direction. The source line SL is formed of, for example, a semiconductor material containing silicon. The source line SL is formed of, for example, polysilicon doped with impurities. However, the material of the source line SL is not limited to the above example. The source line SL may be formed of a metal material such as tungsten or molybdenum. The thickness of the source line SL in the Z direction is, for example, greater than the sum of the thickness of the gate electrode layer 41 in the Z direction and the thickness of the insulating layer 42 in the Z direction.

In this embodiment, the source line SL extends across the array region AR and the hook-up region FR. The source line SL includes a first part SLa disposed in the array region AR and a second part SLb disposed in the hook-up region FR. In this embodiment, the first part SLa and the second part SLb have different thicknesses in the Z direction. A thickness T1 of the first part SLa in the Z direction is greater than a thickness T2 of the second part SLb in the Z direction. For example, the thickness T1 of the first part SLa in the Z direction is more than twice the thickness T2 of the second part SLb in the Z direction. A step is provided between the first part SLa and the second part SLb.

### A4.4 Insulating Part of Hook-Up Region

The insulating part 45 is an insulating part provided in the hook-up region FR.

The insulating part 45 is formed using, for example, TEOS (tetraethyl orthosilicate (Si(OC₂H₅)₄)). A part of the insulating part 45 covers the ends of the plurality of gate electrode layers 41A disposed in a stepped shape from the side in the −Z direction. A part of the insulating part 45 covers the ends of the plurality of gate electrode layers 41B disposed in a stepped shape from the side in the −Z direction. A part of the insulating part 45 is disposed between the second part SLb of the source line SL and the first multi-layered body 40A, and covers the second part SLb of the source line SL from the side in the −Z direction.

### A4.5 Lower Bit Line

The lower bit line BLA is an electrical connection line for selecting one lower columnar part 91 from among the lower columnar parts 91 to be described later. The plurality of lower bit lines BLA are disposed on the lower side (the side in the −Z direction) of the first multi-layered body 40A. The plurality of lower bit lines BLA are disposed on a side of the source line SL opposite to the first multi-layered body 40A. The plurality of lower bit lines BLA are spaced apart from each other in the X direction and arranged in the X direction. The lower bit lines BLA extend in the Y direction (refer to FIG. 6). The lower bit lines BLA extend to pass below the plurality of corresponding lower columnar parts 91.

The lower bit line BLA is electrically connected to the channel layer 72 of the lower columnar part 91, which will be described later, via a contact VY and the contact CH. Therefore, it is possible to select any memory cell transistor MT from among the plurality of memory cell transistors MT disposed three-dimensionally in the first multi-layered body 40A by combining the word line WLA and the lower bit line BLA.

### A4.6 Upper Bit Line

The upper bit line BLB is an electrical connection line for selecting one upper columnar part 92 from among the plurality of upper columnar parts 92 to be described below. The plurality of upper bit lines BLB are disposed on the upper side (the side in the +Z direction) of the second multi-layered body 40B. The plurality of upper bit lines BLB are disposed on a side of the second multi-layered body 40B opposite to the source line SL. The plurality of upper bit lines BLB are spaced apart from each other in the X direction and arranged in the X direction. The upper bit lines BLB extend in the Y direction (refer to FIG. 6). The upper bit lines BLB extend to pass above the plurality of corresponding upper columnar parts 92.

The upper bit line BLB is electrically connected to the channel layer 72 of the upper columnar part 92, which will be described later, via the contact VY and the contact CH. Therefore, it is possible to select any memory cell transistor MT from among the plurality of memory cell transistors MT disposed three-dimensionally in the second multi-layered body 40B by combining the word line WLB and the upper bit line BLB.

### A4.7 Contact for Gate Electrode Layer

The contacts CC are electrical connection parts. The electrical connection parts electrically connect the gate electrode layer 41 and the electrical connection lines 63 (described later) included in the wiring part 60. The plurality of contacts CC are provided, for example, in the hook-up region FR of the memory cell array 11. The plurality of contacts CC extend in the Z direction within the multi-layered body 40. The plurality of contacts CC have different lengths in the Z direction. The plurality of contacts CC are connected to different gate electrode layers 41. The contacts CC have conductivity. The contacts CC are formed of a conductive material (for example, tungsten, molybdenum, or silicon doped with impurities).

In this embodiment, the contacts CC are connected to the plurality of gate electrode layers 41A included in the first multi-layered body 40A from the side in the −Z direction. Similarly, the contacts CC are connected to the plurality of gate electrode layers 41B included in the second multi-layered body 40B from the side in the −Z direction.

### A4.8 Separation Part

Next, the Separation Part 50 Will Be Described.

FIG. 6 is a cross-sectional view showing the semiconductor storage device shown in FIG. 4 taken along line F6-F6. A plurality of separation parts 50 are provided in the multi-layered body 40. The plurality of separation parts 50 are disposed separately in the Y direction. The plurality of separation parts 50 extend in the Z direction within the multi-layered body 40. The plurality of separation parts 50 separate one or more gate electrode layers 41, including the lowermost layer or the uppermost layer, among the plurality of gate electrode layers in the Y direction. The plurality of separation parts 50 include, for example, a plurality of separation parts ST (only one is shown in FIG. 6) and a plurality of separation parts SHE.

### Separation Part ST

The separation part ST is a wall part. The wall part separates the multi-layered body 40 in the Y direction. The plurality of separation parts ST are disposed separately in the Y direction. The separation parts ST extend in the Z direction. The separation parts ST penetrate the multi-layered body 40. For example, the separation parts ST penetrate the first multi-layered body 40A, the source line SL, and the second multi-layered body 40B in the Z direction.

The separation part ST extends in the X direction (refer to FIG. 7). For example, the separation part ST extends in the X direction across the array region AR and the hook-up region FR. The separation part ST is a wall part extending in the X direction and the Z direction. The separation part ST separates each of all of the gate electrode layers 41 (all the gate electrode layers 41A and all of the gate electrode layers 41B) included in the multi-layered body 40 in the Y direction. In this embodiment, in the first multi-layered body 40A, a region sandwiched between two separation parts ST adjacent to each other in the Y direction corresponds to one block BLKA. Similarly, in the second multi-layered body 40B, a region sandwiched between two separation parts ST adjacent to each other in the Y direction corresponds to one block BLKB.

In this embodiment, the separation part ST includes an insulating film 51 and a conductive layer (conductive part) 52. The insulating film 51 extends in the Z direction. The insulating film 51 penetrates the multi-layered body 40. The insulating film 51 is provided over the entire length of the separation part ST in the X direction. The insulating film 51 covers the conductive layer 52. The insulating film 51 includes an insulating film 51s1 and an insulating film 51s2. The insulating film 51s1 forms the surface of the separation part ST on the side in the +Y direction. The insulating film 51s2 forms the surface of the separation part ST on the side in the −direction. The insulating film 51 is formed by, for example, a film containing silicon and oxygen (for example, a silicon oxide film).

The conductive layer 52 is provided inside the insulating film 51. For example, the conductive layer 52 is provided between the insulating film 51s1 and the insulating film 51s2 in the Y direction. The conductive layer 52 extends in the Z direction. The conductive layer 52 penetrates the multi-layered body 40. The conductive layer 52 is formed of a conductive material such as tungsten, molybdenum, or silicon doped with impurities. The upper end of the conductive layer 52 is electrically connected to the electrical connection line 64 in the memory cell array 11 via a contact 55 and a contact 56.

In this embodiment, the separation part ST includes a first part STa and a second part STb. The insulating film 51 and the conductive layer 52 mentioned above are provided across the first part STa and the second part STb.

The first part STa penetrates the first multi-layered body 40A in the Z direction. The first part STa separates each of the plurality of gate electrode layers 41A in the Y direction. The first part STa extends from the lower side to the upper side of the first multi-layered body 40A. The upper end of the first part STa is located inside the source line SL.

The second part STb is provided on the upper side (the side in the +Z direction) of the first part STa. The second part STb penetrates the second multi-layered body 40B in the Z direction. The second part STb separates each of the plurality of gate electrode layers 41B in the Y direction. The second part STb extends from the lower side to the upper side of the second multi-layered body 40B. The lower end of the second part STb is located inside the source line SL. The lower end of the second part STb is connected to the upper end of the first part STa inside the source line SL. A boundary between the first part STa and the second part STb is located inside the source line SL.

A width W1 of the first part STa in the Y direction is larger than a width W2 of the second part STb in the Y direction. For example, the width W1 of the first part STa in the Y direction is larger than the width W2 of the second part STb in the Y direction by more than twice the thickness of the insulating film 51s1 in the Y direction. At the boundary between the first part STa and the second part STb, a step Ts is formed based on a difference between the width W1 of the first part STa in the Y direction and the width W2 of the second part STb in the Y direction. The step Ts is a step in the Y direction. The step Ts is located inside the source line SL.

In this embodiment, the insulating film 51 is not provided at the step Ts of the separation part ST. The insulating film 51 is separated in the Y direction at the boundary (step Ts) between the first part STa and the second part STb of the separation part ST.

For example, the insulating film 51 includes a first insulating film 51a located in the first part STa of the separation part ST and a second insulating film 51b located in the second part STb of the separation part ST. The first insulating film 51a extends in the Z direction in the first part STa. The first insulating film 51a is located between the conductive layer 52 and the plurality of gate electrode layers 41A. The second insulating film 51b extends in the Z direction in the second part STb. The second insulating film 51b is located between the conductive layer 52 and the plurality of gate electrode layers 41B. In this embodiment, the first insulating film 51a and the second insulating film 51b are separated in the Y direction at the step Ts.

On the other hand, the conductive layer 52 is provided in the first part STa and the second part STb. For example, the conductive layer 52 is continuous across the first part STa and the second part STb. For this reason, in a region (step Ts) where the insulating film 51 is separated, the conductive layer 52 is exposed to the outside of the separation part 50 (outside of the insulating film 51) and connected to the source line SL. Therefore, the conductive layer 52 and the source line SL are electrically connected. A voltage is applied to the source line SL via the electrical connection line 64, the contacts 55 and 56, which will be described later, and the conductive layer 52 of the separation part ST.

### Separation Part SHE

The separation part SHE is a separation part that is shorter in length in the Z direction than the separation part ST. The separation part SHE is a wall part. The wall part separates the lower end part or the upper end part of the multi-layered body 40 in the Y direction. The plurality of separation parts SHE include, for example, a plurality of separation parts SHEA and a plurality of separation parts SHEB.

The separation part SHEA is a wall part. The wall part separates the lower end part of the first multi-layered body 40A in the Y direction. The plurality of separation parts SHEA are disposed separately in the Y direction. In this embodiment, a plurality of (for example, three) separation parts SHEA are provided between two separation parts ST adjacent to each other in the Y direction. The separation part SHEA extends in the Z direction to the middle of the first multi-layered body 40A. The separation part SHEA extends in the X direction. The separation part SHEA is a wall part extending in the X direction and the Z direction.

The separation part SHEA penetrates parts of the gate electrode layers 41A including the lowermost layer among the plurality of gate electrode layers 41A. The separation part SHEA separates the parts of the gate electrode layers 41A in the Y direction. For example, the separation part SHEA penetrates each of all of the gate electrode layers 41A that function as the drain-side select gate line SGDA. On the other hand, the separation part SHEA does not reach the gate electrode layer 41A that functions as the word line WLA. The separation part SHEA separates only the gate electrode layer 41A that functions as the drain-side select gate line SGDA in the Y direction. The separation part SHEA is formed by, for example, a film containing silicon and oxygen (for example, a silicon oxide film). In this embodiment, a region sandwiched between two separation parts SHEA adjacent to each other in the Y direction corresponds to one string STR.

The separation part SHEB is a wall part. The wall part separates the upper end portion of the second multi-layered body 40B in the Y direction. The plurality of separation parts SHEB are disposed separately in the Y direction. In this embodiment, a plurality of separation parts SHEB (for example, three separation parts SHEB) are provided between two separation parts ST adjacent to each other in the Y direction. The separation part SHEB extends in the Z direction to the middle of the second multi-layered body 40B. The separation part SHEB extends in the X direction. The separation part SHEB is a wall part extending in the X direction and the Z direction.

The separation part SHEB penetrates parts of the gate electrode layers 41B including the uppermost layer among the plurality of gate electrode layers 41B. The separation part SHEB separates the parts of the gate electrode layers 41B in the Y direction. For example, the separation part SHEB penetrates each of all of the gate electrode layers 41B that function as the drain-side select gate line SGDB. On the other hand, the separation part SHEB does not reach the gate electrode layer 41B that functions as the word line WLB. The separation part SHEB separates only the gate electrode layer 41B that functions as the drain-side select gate line SGDB in the Y direction. The separation part SHEB is formed by, for example, a film containing silicon and oxygen (for example, a silicon oxide film). In this embodiment, a region sandwiched between two separation parts SHEB adjacent to each other in the Y direction corresponds to one string STR.

### A4.9 Wiring Part

The wiring part 60 is an electrical connection part. The electrical connection part electrically connects the plurality of pads 32 and each component included in the memory cell array 11. The wiring part 60 includes, for example, a wiring part 60A and a wiring part 60B.

The wiring part 60A is a wiring part disposed between the first multi-layered body 40A and the semiconductor substrate 21. The wiring part 60A includes, for example, a plurality of electrical connection lines 61, a plurality of electrical connection lines 62, and a plurality of electrical connection lines 63 (refer to FIG. 5).

The plurality of electrical connection lines 61 are disposed, for example, below (in the −Z direction) the plurality of lower bit lines BLA. The electrical connection lines 61 extend, for example, in the X direction or the Y direction. Between the electrical connection lines 61 and the lower bit lines BLA, vias VA are provided. The vias VA electrically connect the electrical connection lines 61 and the lower bit lines BLA.

The electrical connection line 61 electrically connects the peripheral circuit (for example, the sense amplifier unit 17a) and the lower bit line BLA. For example, the electrical connection line 61 electrically connects the switching circuit 19 (for example, the switching circuit 19A) and the lower bit line BLA. For example, the electrical connection line 61 electrically connects the switching element 19Aa of the switching circuit 19A and the lower bit line BLA. In this embodiment, the electrical connection line 61 is electrically connected to the pad 32 for bonding. The electrical connection line 61 is electrically connected to the switching circuit 19A via the pads 24 and 32.

The plurality of electrical connection lines 62 are disposed, for example, below (in the −Z direction) the plurality of contacts CS (only one is shown in FIG. 6) provided in the bit line tap region BR. The electrical connection lines 62 extend, for example, in the X direction or the Y direction. Between the electrical connection lines 62 and the contacts CS, contacts VB are provided. The contacts VB electrically connect the electrical connection lines 62 and the contacts CS.

The electrical connection line 62 electrically connects the peripheral circuit (for example, the sense amplifier unit 17a) and the contact CS. For example, the electrical connection line 62 electrically connects the switching circuit 19 (for example, the switching circuit 19B) and the contact CS. For example, the electrical connection line 62 electrically connects the switching element 19Ba of the switching circuit 19B and the contact CS. In this embodiment, the electrical connection line 62 is electrically connected to the pad 32 for bonding. The electrical connection line 62 is electrically connected to the switching circuit 19B via the pads 24 and 32.

The electrical connection line 63 electrically connects the peripheral circuit and the contact CC (refer to FIG. 5). In this embodiment, the electrical connection line 63 is electrically connected to the pad 32 for bonding. A voltage for selecting the gate electrode layer 41 (the word line WL, the drain-side select gate line SGD, or the source-side select gate line SGS) is applied to the electrical connection line 63.

### A5. Structure of Bit Line Tap Region

Next, the structure of the bit line tap region BR will be described.

As shown in FIG. 6, the bit line tap region BR includes a third multi-layered body 40C, a fourth multi-layered body 40D, an insulating part 47, and a plurality of contacts CS (only one is shown in FIG. 6).

### A5.1 Third Multi-Layered Body

The third multi-layered body 40C is a multi-layered body located around a part of the contact CS. The third multi-layered body 40C includes, for example, a plurality of insulating layers 46A and a plurality of insulating layers 42A. The plurality of insulating layers 46A and the plurality of insulating layers 42A are alternately stacked one by one in the Z direction.

The insulating layer 46A is located at the same height as the gate electrode layer 41A. The insulating layer 46A extends in the X direction and the Y direction. The insulating layer 46A is connected to the gate electrode layer 41A in the Y direction. For example, the insulating layer 46A is formed by a part of a sacrificial layer (sacrificial layer 111A to be described later), which is to be replaced by the gate electrode layer 41A during the manufacturing process, remaining unreplaced. The insulating layer 46A is formed of a material different from that of the insulating layer 42A. The insulating layer 46A is formed by, for example, a film containing silicon and nitrogen (for example, a silicon nitride film).

The insulating layer 42A is provided between two insulating layers 46A adjacent to each other in the Z direction. The insulating layer 42A extends in the X direction and the Y direction. The insulating layer 42A is formed by, for example, a film containing silicon and oxygen (for example, a silicon oxide film). The insulating layer 42A included in the bit line tap region BR is located at the same height as the insulating layer 42A included in the array region AR. The insulating layer 42A included in the bit line tap region BR is continuous with the insulating layer 42A included in the array region AR.

### A5.2 Fourth Multi-Layered Body

The fourth multi-layered body 40D is a multi-layered body located around another part of the contact CS. The fourth multi-layered body 40D is disposed on the upper side (the side in the +Z direction) of the third multi-layered body 40C. The fourth multi-layered body 40D includes, for example, a plurality of insulating layers 46B and a plurality of insulating layers 42B. The plurality of insulating layers 46B and the plurality of insulating layers 42B are alternately stacked one by one in the Z direction.

The insulating layer 46B is located at the same height as the gate electrode layer 41B. The insulating layer 46B extends in the X direction and the Y direction. The insulating layer 46B is connected to the gate electrode layer 41B in the Y direction. For example, the insulating layer 46B is formed by a part of a sacrificial layer (sacrificial layer 111B to be described later), which is to be replaced by the gate electrode layer 41B during the manufacturing process, remaining unreplaced. The insulating layer 46B is formed of a material different from that of the insulating layer 42B. The insulating layer 46B is formed by, for example, a film containing silicon and nitrogen (for example, a silicon nitride film).

The insulating layer 42B is provided between two insulating layers 46B adjacent to each other in the Z direction. The insulating layer 42B extends in the X direction and the Y direction. The insulating layer 42B is formed by, for example, a film containing silicon and oxygen (for example, a silicon oxide film). The insulating layer 42B included in the bit line tap region BR is located at the same height as the insulating layer 42B included in the array region AR. The insulating layer 42B included in the bit line tap region BR is continuous with the insulating layer 42B included in the array region AR.

### A5.3 Insulating Part

The insulating part 47 is disposed between the third multi-layered body 40C and the fourth multi-layered body 40D in the Z direction. A gap between the third multi-layered body 40C and the fourth multi-layered body 40D is filled with the insulating part 47. The insulating part 47 is adjacent to the source line SL in the Y direction.

### A5.4 Contact

The contact CS is an electrical connection part. The electrical connection part electrically connects the peripheral circuit (for example, the sense amplifier unit 17a) and the upper bit line BLB. In this embodiment, the contact CS electrically connects the switching circuit 19 and the upper bit line BLB. For example, the contact CS electrically connects the switching element 19Ba of the switching circuit 19B and the upper bit line BLB.

In this embodiment, the contact CS is a columnar body extending in the Z direction. The contact CS penetrates the third multi-layered body 40C, the fourth multi-layered body 40D, and the insulating part 47 in the Z direction. The contact CS extends across the lower side of the third multi-layered body 40C and the upper side of the fourth multi-layered body 40D.

The upper end of the contact VB is electrically connected to the upper bit line BLB, for example, via the contact VC. The lower end of the contact CS is electrically connected to the switching circuit 19, for example, via the contact VB. Note that, in another example of the semiconductor storage device 1, the switching circuit 19 may not be provided. In a structure in which the switching circuit 19 is not provided, the lower end of the contact CS is electrically connected to the sense amplifier unit 17a, for example, via the contact VB.

FIG. 7 is an enlarged view showing a region surrounded by a F7 line in the structure shown in FIG. 4. As shown in FIG. 7, the upper bit line BLB extends in the Y direction so as to overlap the contact CS and a plurality of blocks BLK when viewed from the Z direction.

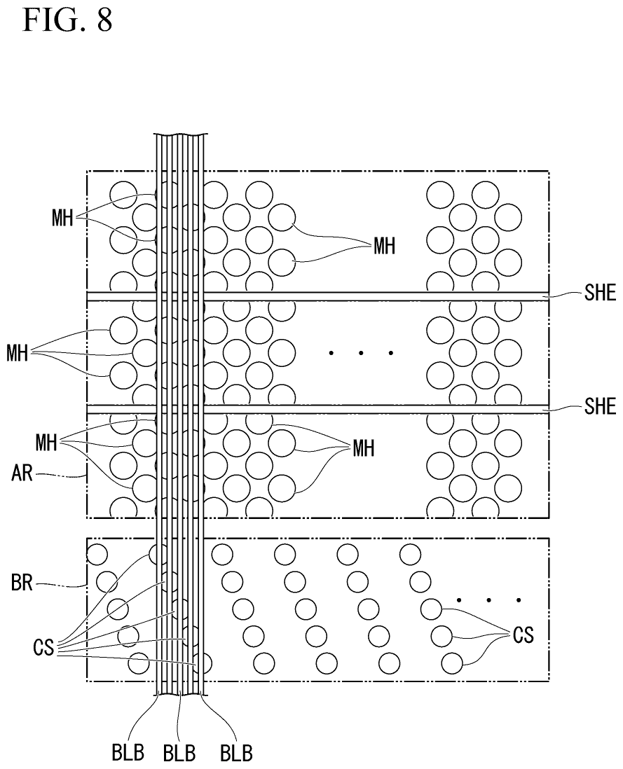

FIG. 8 is an enlarged view showing a region surrounded by F8 line in the structure shown in FIG. 7. As shown in FIG. 7, in the bit line tap region BR, a plurality of contacts CS are disposed apart from each other. For example, a plurality of contacts CS are disposed to be shifted in the X direction and the Y direction. A plurality of upper bit lines BLB are electrically connected to corresponding contacts CS in a one-to-one relationship in the bit line tap region BR via the contacts VC mentioned above.

### A6. Memory Pillar

### A6.1 Internal Structure of Memory Pillar

Next, the memory pillar MH will be described. A plurality of memory pillars MH are arranged in the X direction and the Y direction (refer to FIG. 7). The memory pillars MH extend in the Z direction within the multi-layered body 40. The memory pillars MH penetrate the multi-layered body 40. The memory pillar MH is an example of a “columnar body”.

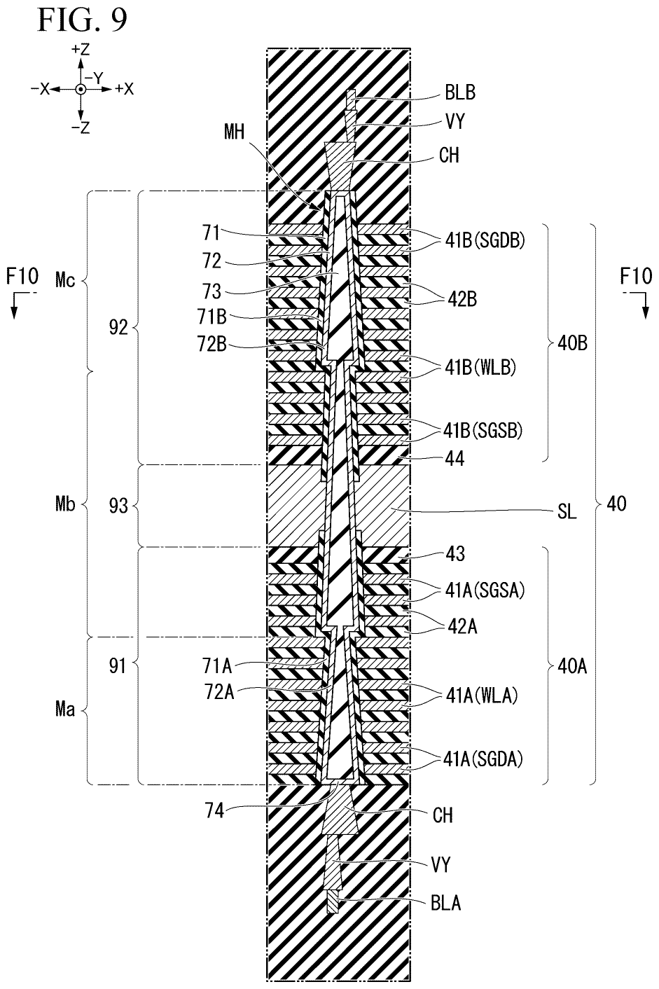

FIG. 9 is a cross-sectional view showing the memory pillar MH. The memory pillar MH includes, for example, a memory film (multilayer film) 71, a channel layer 72, an insulating part 73, and a cap part 74.

The memory film 71 is disposed at the outer peripheral part of the memory pillar MH. The memory film 71 extends in the Z direction. For example, the memory film 71 is disposed to extend over the entire length of the memory pillar MH in the Z direction, except for the upper end part and the middle part of the memory pillar MH. The memory film 71 is located between the plurality of gate electrode layers 41 and the channel layer 72.

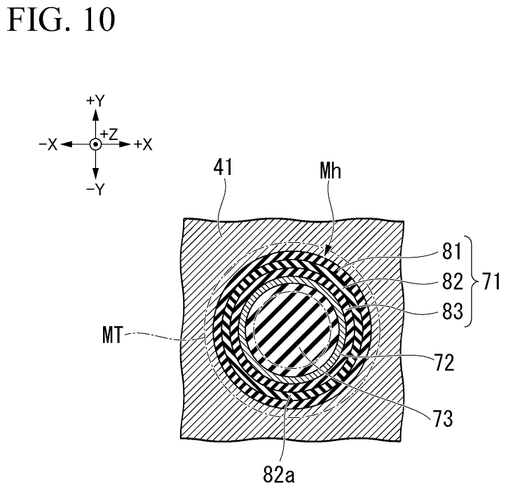

FIG. 10 is a cross-sectional view showing the structure shown in FIG. 9 taken along line F10-F10. The memory film 71 includes, for example, a block insulating film 81, a charge trap film 82, and a tunnel insulating film 83.

The block insulating film 81 is disposed at the outermost peripheral part of the memory pillar MH. The block insulating film 81 is provided between the plurality of gate electrode layers 41 and the charge trap film 82. The block insulating film 81 is an insulating film that suppresses back tunneling. The back tunneling is a phenomenon in which charges return from the word line WL to the charge trap film 82. The block insulating film 81 is formed in a ring shape. The block insulating film 81 extends in the Z direction. The block insulating film 81 is provided, for example, over the entire length of the memory pillar MH in the Z direction, except for the upper end part and the middle part of the memory pillar MH. The block insulating film 81 is a stacked structure film including a plurality of insulating films stacked therein. The plurality of insulating films are, for example, a film containing silicon and oxygen or a film containing a metal and oxygen. An example of the film containing a metal and oxygen is an aluminum oxide film. The block insulating film 81 may also contain a high-k material such as silicon nitride or hafnium oxide.

The charge trap film 82 is provided on the inner periphery side of the block insulating film 81 in the X direction and the Y direction. The charge trap film 82 is located between the block insulating film 81 and the tunnel insulating film 83. The charge trap film 82 is formed in a ring shape. The charge trap film 82 extends in the Z direction. For example, the charge trap film 82 is provided over the entire length of the memory pillar MH in the Z direction, except for the upper end part and the middle part of the memory pillar MH. The charge trap film 82 is a functional film. The functional film has a large number of crystal defects (trapping levels) and is capable of trapping charges in the crystal defects. The charge trap film 82 is formed by, for example, a film containing silicon and nitrogen. The parts of the charge trap film 82 which are adjacent to the word lines WL form an example of a “charge storage part 82a” capable of storing information by storing charges.

The tunnel insulating film 83 is provided on the inner periphery side of the charge trap film 82 in the X direction and the Y direction. The tunnel insulating film 83 is provided between the charge trap film 82 and the channel layer 72. The tunnel insulating film 83 is formed, for example, in a ring shape along the outer peripheral surface of the channel layer 72. The tunnel insulating film 83 extends in the Z direction along the channel layer 72. The insulating film 83 is provided over the entire length of the memory pillar MH in the Z direction, except for the upper end part and the middle part of the memory pillar MH. The tunnel insulating film 83 is a potential barrier between the charge trap film 82 and the channel layer 72. The tunnel insulating film 83 is formed by a film containing silicon and oxygen, or a film containing silicon, oxygen, and nitrogen.

The channel layer 72 is provided on the inner periphery side of the memory film 71 in the X direction and the Y direction. The channel layer 72 is formed in a ring shape. The channel layer 72 extends in the Z direction. For example, the channel layer 72 is provided over the entire length of the memory pillar MH in the Z direction. The channel layer 72 is formed of a semiconductor material such as polysilicon. The channel layer 72 may be doped with impurities. When a voltage is applied to the word line WL, the channel layer 72 forms a channel and electrically connects the bit line BL and the source line SL. The channel layer 72 is an example of a “semiconductor film”.

With the above-described configuration, a MANOS (metal-al-nitride-oxide-silicon) type memory cell transistor MT is formed at the same height as each word line WL. The memory cell transistor MT is formed by the edge of the word line WL adjacent to the memory pillar MH, the block insulating film 81, the charge trap film 82, the tunnel insulating film 83, and the channel layer 72. Note that, the memory film 71 may include a floating gate type charge storage part (floating gate electrode) as the charge storage part instead of the charge trap film 82. The floating gate type charge storage part is formed of, for example, polysilicon containing impurities.

Returning back to FIG. 9, the remaining configuration of the memory pillar MH will be described.

The insulating part 73 is provided on the inner periphery side of the channel layer 72 in the X direction and the Y direction. At least a part of the inside of the channel layer 72 is filled with the insulating part 73. The insulating part 73 is formed by a film containing silicon and oxygen (for example, a silicon oxide film). The insulating part 73 extends in the Z direction. For example, the insulating part 73 is provided over the entire length of the memory pillar MH in the Z direction, except for the lower end part of the memory pillar MH.

The cap part 74 is provided below the insulating part 73. The cap part 74 is a semiconductor part formed of a semiconductor material such as amorphous silicon or polysilicon. For example, the cap part 74 may be doped with impurities. The cap part 74 is disposed on the inner periphery side of the lower end part of the memory film 71. The cap part 74 is formed integrally with the channel layer 72. The cap part 74 forms the lower end part of the memory pillar MH, together with the lower end part of the channel layer 72.

### A6.2 Multi-Stage Structure of Memory Pillar

In this embodiment, the memory pillar MH is formed by a plurality of stages (for example, three stages) of columnar bodies. For example, the memory pillar MH includes columnar bodies Ma, Mb, and Mc. Each of the columnar bodies Ma, Mb, and Mc includes the memory film (multilayer film) 71, the channel layer 72, and the insulating part 73 mentioned above.

The columnar body Ma on the lower side is provided in the first multi-layered body 40A. The columnar body Ma extends in the Z direction inside the first multi-layered body 40A. The lower end of the columnar body Ma is electrically connected to the lower bit line BLA via the contact CH and the contact VY. The upper end of the columnar body Ma is located inside the first multi-layered body 40A. As the columnar body Ma moves from the upper side to the lower side, the circumference (diameter) of the columnar body Ma in the cross-section in the X direction and the Y direction gradually increases.

The columnar body Mb at the middle level is provided on the upper side (the side in the +Z direction) of the columnar body Ma. The columnar body Mb is provided over the first multi-layered body 40A and the second multi-layered body 40B. The columnar body Mb penetrates the source line SL in the Z direction. The columnar body Mb extends in the Z direction inside the first multi-layered body 40A and inside the second multi-layered body 40B. The lower end of the columnar body Mb is connected to the upper end of the columnar body Ma inside the first multi-layered body 40A. The upper end of the columnar body Mb is connected to the lower end of the columnar body Mc inside the second multi-layered body 40B. As the columnar body Mb moves from the upper side to the lower side, the circumference (diameter) of the columnar body Mb in the cross-section in the X direction and the Y direction gradually increases.

The columnar body Mc at the upper level is provided on the upper side (the side in the +Z direction) of the columnar body Mb. The columnar body Mc is provided in the second multi-layered body 40B. The columnar body Mc extends in the Z direction inside the second multi-layered body 40B. The upper end of the columnar body Mc is electrically connected to the upper bit line BLB via the contact CH and the contact VY. As the columnar body Mc moves from the upper side to the lower side, the circumference (diameter) of the columnar body Mc in the cross-section in the X direction and the Y direction gradually increases.

Note that, the configuration of the memory pillar MH is not limited to the above example. For example, instead of the structure formed by three stages of columnar bodies, the memory pillar MH may be formed by one or two stages of columnar bodies, or four or more stages of columnar bodies.

### A6.3 Lower Columnar Part and Upper Columnar Part As shown in FIG. 9, the memory pillar MH includes a lower columnar part 91, an upper columnar part 92, and an intermediate part 93.

### Lower Columnar Part

The lower columnar part 91 is a part of the memory pillar MH which is provided corresponding to the first multi-layered body 40A. The lower columnar part 91 extends in the Z direction within the first multi-layered body 40A and penetrates the first multi-layered body 40A in the Z direction. In this embodiment, the lower columnar part 91 is formed by the entire columnar body Ma and the lower part of the columnar body Mb. In this embodiment, a first occupying part that occupies more than half of the lower columnar part 91 in the Z direction is a part in which the first circumference (diameter) of the lower columnar part 91 in the cross-section in the X direction and the Y direction gradually increases in a direction from the upper side toward the lower side.

In other words, the lower columnar part 91 has a first occupying part. The first occupying part occupies more than half of a region configuring the lower columnar part 91 in the first direction. The lower columnar part 91 has a first circumference in a cross-section intersecting the first direction in the first occupying part. The first circumference increases in a direction from the first side to the second side.

The lower columnar part 91 includes a part of each of the memory film 71, the channel layer 72, and the insulating part 73, as well as the cap part 74. For convenience of description, a part of the memory film 71 included in the lower columnar part 91 may be referred to as a “lower memory film 71A” below. The lower memory film 71A is an example of a “first memory film”. In addition, for convenience of description, a part of the channel layer 72 included in the lower columnar part 91 may be referred to as a “lower semiconductor film 72A” below. The lower semiconductor film 72A is an example of a “first semiconductor film”.

The contact CH is in contact with the lower end of the lower columnar part 91 from the side in the −direction. The lower end of the channel layer 72 (lower semiconductor film 72A) of the lower columnar part 91 is electrically connected to the lower bit line BLA via the contact CH and the contact VY. The upper end of the channel layer 72 (lower semiconductor film 72A) of the lower columnar part 91 is electrically connected to the source line SL via the intermediate part 93 to be described below.

### Upper Columnar Part

The upper columnar part 92 is disposed on the upper side (the side in the +Z direction) of the lower columnar part 91. The upper columnar part 92 is a part of the memory pillar MH which is provided corresponding to the second multi-layered body 40B. The upper columnar part 92 extends in the Z direction within the second multi-layered body 40B. The upper columnar part 92 penetrates the second multi-layered body 40B in the Z direction. In this embodiment, the upper columnar part 92 is formed by the entire columnar body Mc and the upper part of the columnar body Mb. In this embodiment, the lower columnar part 91 and the upper columnar part 92 overlap each other when viewed from the Z direction. In this embodiment, a second occupying part that occupies more than half of the upper columnar part 92 in the Z direction is a part in which the second circumference (diameter) of the upper columnar part 92 in the cross-section in the X direction and the Y direction gradually increases in a direction from the upper side to the lower side.

In other words, the upper columnar part 92 has a second occupying part. The second occupying part occupies more than half of a region configuring the upper columnar part 92 in the first direction. The upper columnar part 92 has a second circumference in a cross-section intersecting the first direction in the second occupying part. The second circumference increases in a direction from the first side toward the second side.

The upper columnar part 92 includes a part of each of the memory film 71, the channel layer 72, and the insulating part 73. For convenience of description, a part of the memory film 71 included in the upper columnar part 92 may be referred to as an “upper memory film 71B”. The upper memory film 71B is an example of a “second memory film”. In addition, for convenience of description, a part of the channel layer 72 included in the upper columnar part 92 may be referred to as an “upper semiconductor film 72B”. The upper semiconductor film 72B is an example of a “second semiconductor film”.

The contact CH is in contact with the upper end of the upper columnar part 92 from the side in the +Z direction. The upper end of the channel layer 72 (upper semiconductor film 72B) of the upper columnar part 92 is electrically connected to the upper bit line BLB via the contact CH and the contact VY. The lower end of the channel layer 72 (upper semiconductor film 72B) of the upper columnar part 92 is electrically connected to the source line SL via the intermediate part 93 to be described later.

### Intermediate Part

The intermediate part (intermediate columnar part) 93 is provided between the lower columnar part 91 and the upper columnar part 92 in the Z direction. The intermediate part 93 penetrates the source line SL in the Z direction. In this embodiment, the intermediate part 93 is formed by a part of the columnar body Mb. The intermediate part 93 includes a part of each of the memory film 71, the channel layer 72, and the insulating part 73.

On the other hand, the memory film 71 is not provided in at least a part of the intermediate part 93. In this embodiment, the memory film 71 (lower memory film 71A) of the lower columnar part 91 and the memory film 71 (upper memory film 71B) of the upper columnar part 92 are separated from each other in the Z direction. For this reason, in the intermediate part 93, the channel layer 72 is exposed to the outside of the memory pillar MH and connected to the source line SL in the region where the memory film 71 is not provided (the region between the lower memory film 71A and the upper memory film 71B). Therefore, the channel layer 72 and the source line SL are electrically connected to each other.

### A7. Example of Arrangement of Separation Part and Bit Line Tap Region

### A7.1 Example of Arrangement of Separation Part

As shown in FIG. 6, the separation part ST is disposed between a plurality of memory pillars MH (memory pillars MHA and memory pillars MHB) arranged in the Y direction.

The lower columnar part 91 included in the memory pillar MHA is an example of a “first columnar part”. The lower memory film 71A of the lower columnar part 91 included in the memory pillar MHA is an example of a “first memory film”. The lower semiconductor film 72A of the lower columnar part 91 included in the memory pillar MHA is an example of a “first semiconductor film”.

The upper columnar part 92 included in the memory pillar MHA is an example of a “second columnar part”. The upper memory film 71B of the upper columnar part 92 included in the memory pillar MHA is an example of a “second memory film”. The upper semiconductor film 72B of the upper columnar part 92 included in the memory pillar MHA is an example of a “second semiconductor film”.

From one point of view, the lower columnar part 91 included in the memory pillar MHB is an example of a “third columnar part”. The lower memory film 71A of the lower columnar part 91 included in the memory pillar MHB is an example of a “third memory film”. The lower semiconductor film 72A of the lower columnar part 91 included in the memory pillar MHB is an example of a “third semiconductor film”.

From point of view, the upper columnar part 92 included in the memory pillar MHB is an example of a “fourth columnar part”. The upper memory film 71B of the upper columnar part 92 included in the memory pillar MHA is an example of a “fourth memory film”. The upper semiconductor film 72B of the upper columnar part 92 included in the memory pillar MHB is an example of a “fourth semiconductor film”.

In this embodiment, the conductive layer 52 of the separation part ST is provided in at least one of the two regions described below. One (first region) of the two regions is a region between the lower columnar part 91 (first columnar part) of the memory pillar MHA and the lower columnar part 91 (third columnar part) of the memory pillar MHB. The other (second region) of the two regions is a region between the upper columnar part 92 (second columnar part) of the memory pillar MHA and the upper columnar part 92 (fourth columnar part) of the memory pillar MHB. The conductive layer 52 of the separation part ST extends in the Z direction through the above region and is connected to the source line SL.

### A7.2 Example of Arrangement of Bit Line Tap Region

As shown in FIG. 6, the bit line tap region BR is disposed between a plurality of memory pillars MH (memory pillars MHA and memory pillars MHC) arranged in the Y direction.

From one point of view, the lower columnar part 91 included in the memory pillar MHC is an example of a “fifth columnar part”. The lower memory film 71A of the lower columnar part 91 included in the memory pillar MHC is an example of a “fifth memory film”. The lower semiconductor film 72A of the lower columnar part 91 included in the memory pillar MHC is an example of a “fifth semiconductor film”.

From one point of view, the upper columnar part 92 included in the memory pillar MHC is an example of a “sixth columnar part”. The upper memory film 71B of the upper columnar part 92 included in the memory pillar MHC is an example of a “sixth memory film”. The upper semiconductor film 72B of the upper columnar part 92 included in the memory pillar MHC is an example of a “sixth semiconductor film”.

In this embodiment, the peripheral circuit (for example, the sense amplifier module 17 or the switching circuit 19) is disposed on a side (the side in the −Z direction) of the first multi-layered body 40A opposite to the second multi-layered body 40B. The contacts CS of the bit line tap region BS are provided in two regions to be described below. One (first region) of the two regions is a region between the lower columnar part 91 (first columnar part) of the memory pillar MHA and the lower columnar part 91 (fifth columnar part) of the memory pillar MHC. The other (second region) of the two regions is a region between the upper columnar part 92 (second columnar part) of the memory pillar MHA and the upper columnar part 92 (sixth columnar part) of the memory pillar MHC. The contact CS of the bit line tap region BS extends in the Z direction in the above region. The contact CS of the bit line tap region BS electrically connects the above-described peripheral circuit and the upper bit line BLB.

### A8. Manufacturing Method

Next, a method of manufacturing the semiconductor storage device 1 will be described.

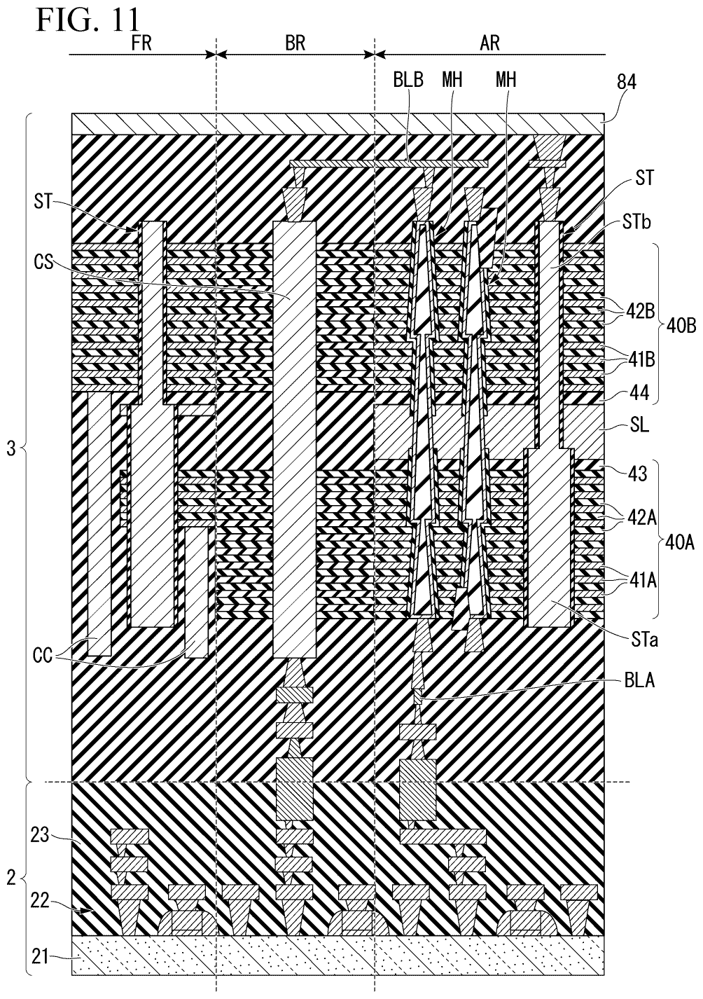

Here, FIG. 11 is a schematic cross-sectional view showing the structure of the semiconductor storage device 1. For convenience of description, FIG. 11 shows the hook-up region FR, the bit line tap region BR, and the array region AR side by side. FIG. 11 schematically shows the structure related to the X direction and the structure related to the Y direction together. Hereinafter, the manufacturing method will be described using the structure shown in FIG. 11 as an example.

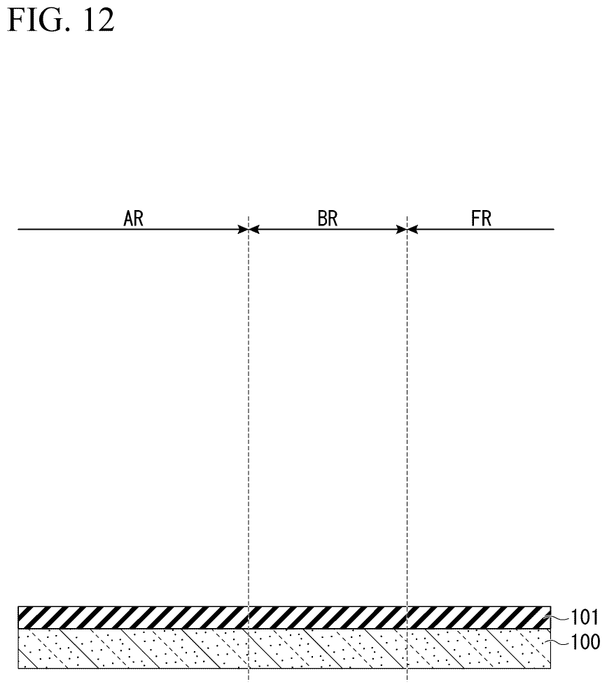

FIG. 12 to FIG. 47 are cross-sectional views showing the method of manufacturing the semiconductor storage device 1. Note that, FIG. 12 to FIG. 47 show the structure in the middle of manufacturing in an upside-down position relative to FIG. 11.

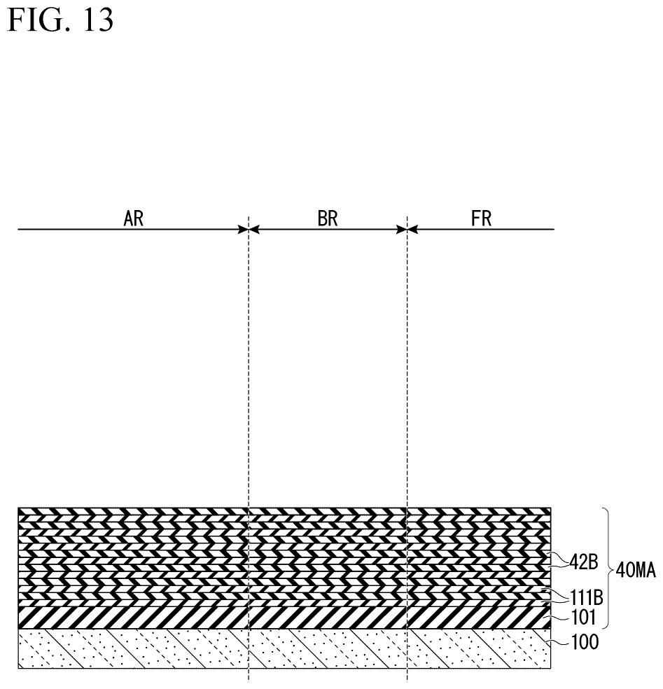

First, as shown in FIG. 12, an insulating layer 101 is formed on a semiconductor substrate 100. The insulating layer 101 is formed by, for example, a film containing silicon and oxygen (for example, a silicon oxide film). Next, as shown in FIG. 13, sacrificial layers 111B and insulating layers 42B are alternately stacked one by one in the Z direction. Therefore, a structure 40MA including the insulating layer 101, the plurality of sacrificial layers 111B, and the plurality of insulating layers 42B is formed. The sacrificial layer 111B is formed by, for example, a film containing silicon and nitrogen (for example, a silicon nitride film).

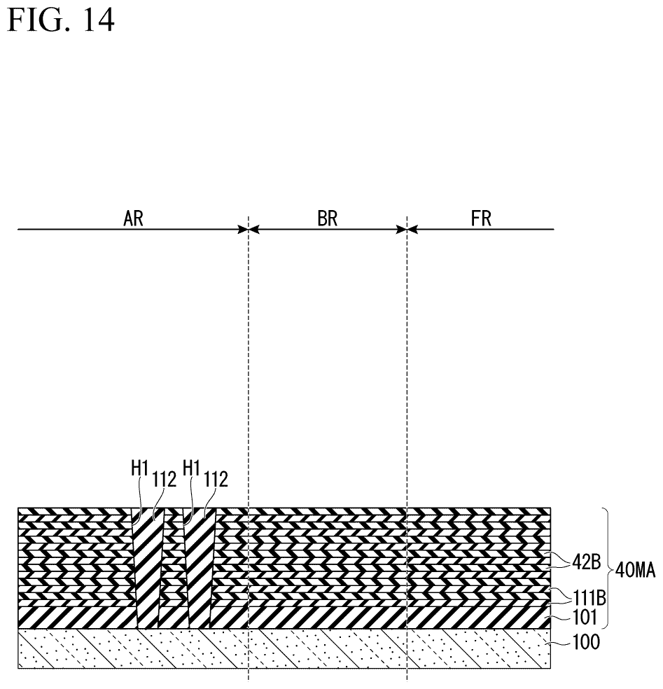

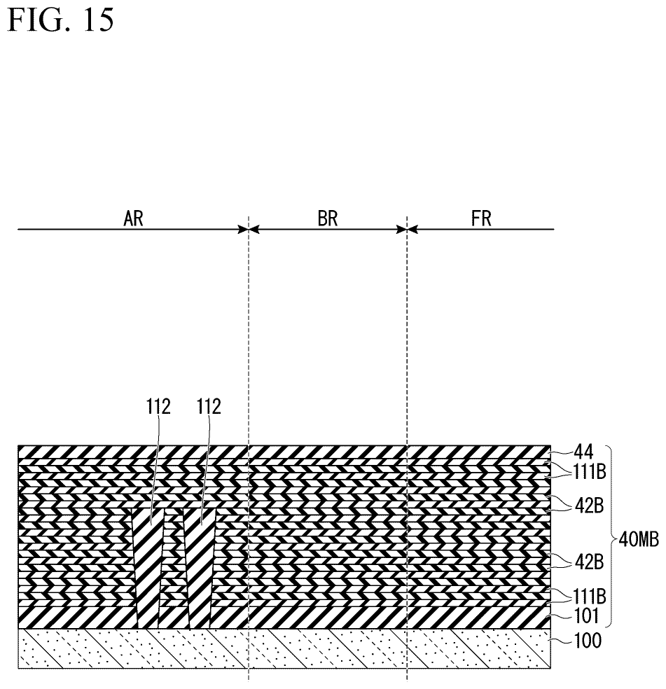

Next, as shown in FIG. 14, holes H1 corresponding to the columnar bodies Mc are formed in the structure 40MA. The holes H1 are filled with a sacrificial material 112. Next, as shown in FIG. 15, the sacrificial layers 111B and the insulating layers 42B are alternately stacked one by one in the Z direction. In addition, the insulating layer 44 is formed on the sacrificial layer 111B serving as the uppermost layer. Therefore, a structure 40MB is formed in which a plurality of sacrificial layers 111B, a plurality of insulating layers 42B, and an insulating layer 44 are added to the structure 40MA. The structure 40MB is an example of a “first-stage multi-layered body”. The sacrificial layer 111B is an example of a “first layer”. The insulating layer 42B is an example of a “second layer”.

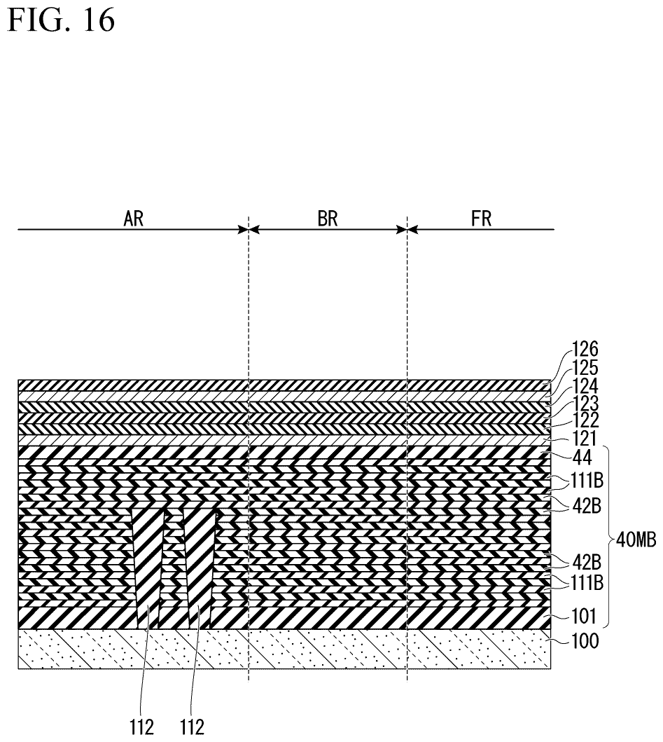

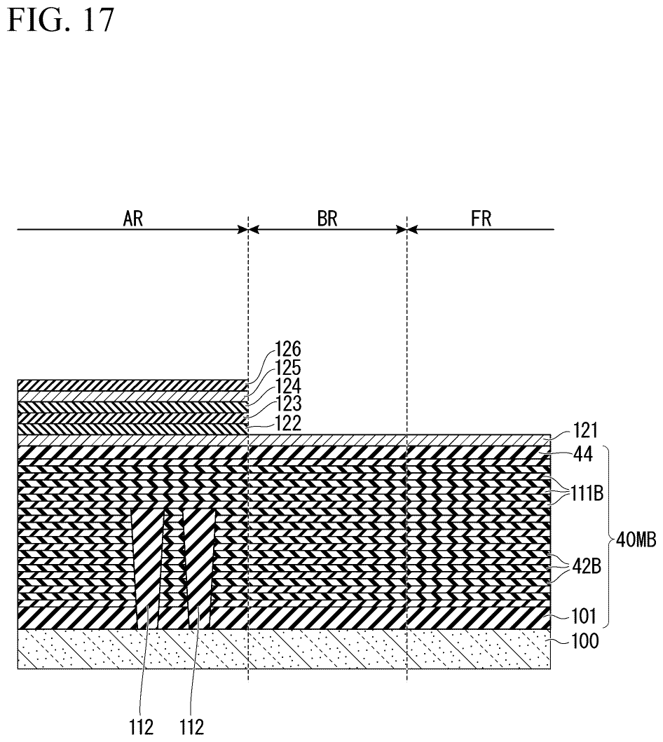

Next, as shown in FIG. 16, a conductive layer 121, a sacrificial layer 122, a sacrificial layer 123, a sacrificial layer 124, a conductive layer 125, and a stopper layer 126 are stacked in this order on the structure 40MB. Each of the conductive layer 121, the sacrificial layer 122, the sacrificial layer 123, the sacrificial layer 124, the conductive layer 125, and the stopper layer 126 extends in the X direction and the Y direction. The conductive layers 121 and 125 are formed of, for example, polysilicon doped with impurities. The sacrificial layers 122 and 124 are formed of, for example, a film containing silicon and oxygen (for example, a silicon oxide film). The sacrificial layer 123 and the stopper layer 126 are formed by a film containing silicon and nitrogen (for example, a silicon nitride film). The sacrificial layer 123 is an example of a “third layer”. Next, as shown in FIG. 17, in the sacrificial layers 122, 123, and 124, the conductive layer 125, and the stopper layer 126, parts included in the bit line tap region BR and the hook-up region FR are removed.

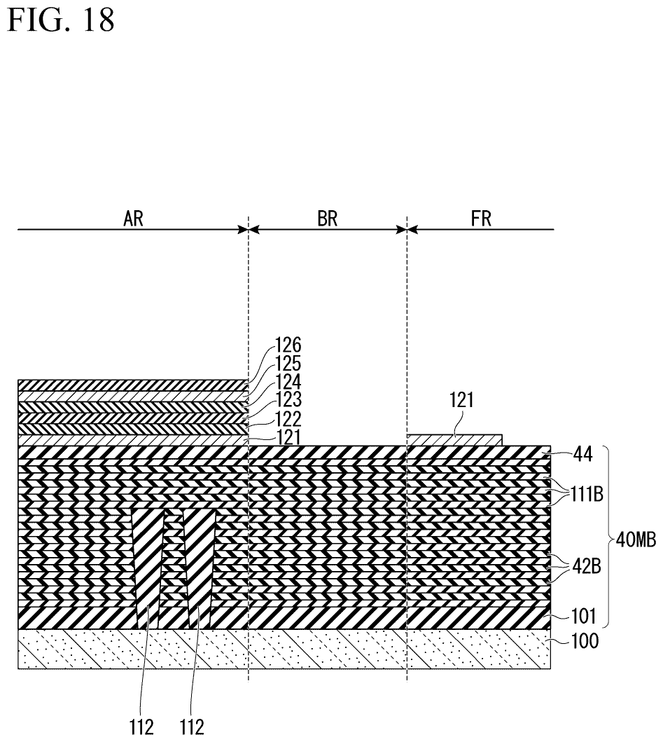

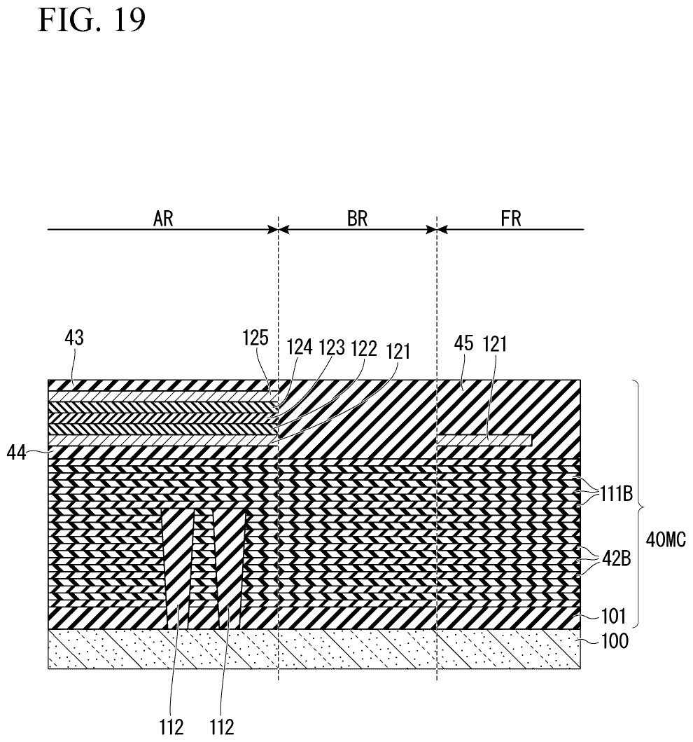

Next, as shown in FIG. 18, in the conductive layer 121, a part included in the bit line tap region BR and an unnecessary part included in the hook-up region FR are removed. Next, as shown in FIG. 19, the stopper layer 126 is removed. Next, TEOS is supplied to the array region AR, the bit line tap region BR, and the hook-up region FR. Therefore, the insulating layer 43, the insulating layer 44, and a part of the insulating part 45 are formed. Therefore, a structure 40MC is formed.

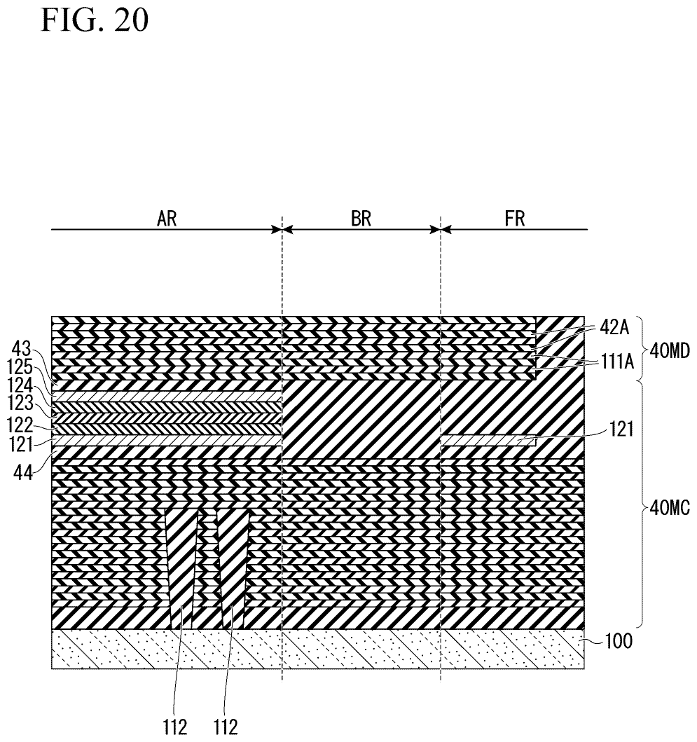

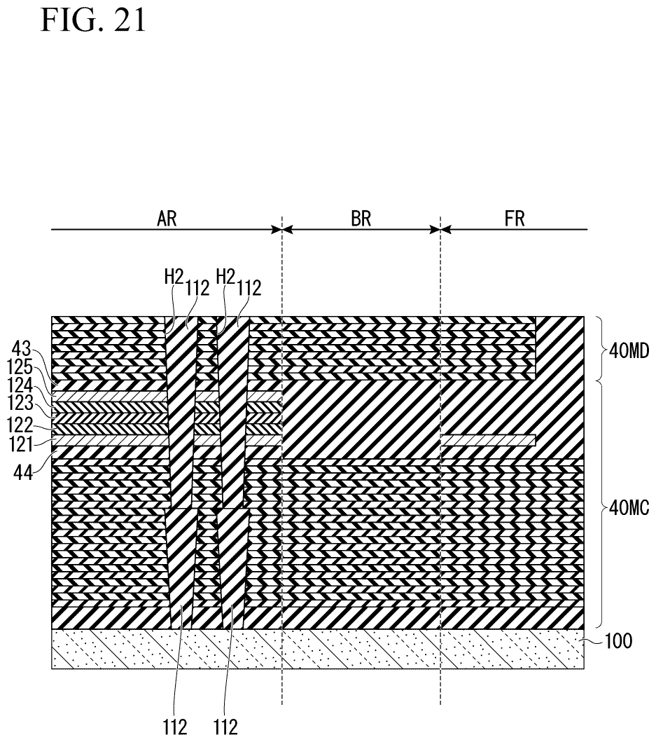

Next, as shown in FIG. 20, the sacrificial layers 111A and the insulating layers 42A are alternately stacked one by one on the structure 40MC in the Z direction. Therefore, a structure 40MD including a plurality of sacrificial layers 111A and a plurality of insulating layers 42A is formed. Next, as shown in FIG. 21, holes H2 corresponding to the columnar bodies Mb are formed. The holes H2 are filled with the sacrificial material 112.

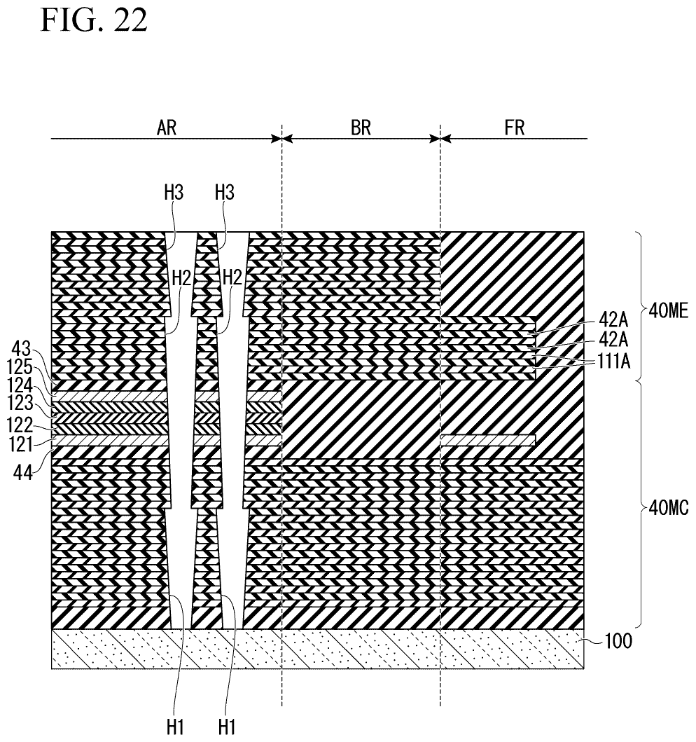

Next, as shown in FIG. 22, the sacrificial layers 111A and the insulating layers 42A are alternately stacked one by one on the structure 40MD in the Z direction. Therefore, a structure 40ME is formed in which a plurality of sacrificial layers 111A and a plurality of insulating layers 42A are added to the structure 40MD. The structure 40ME is an example of a “second-stage multi-layered body”. The sacrificial layer 111A is an example of a “fourth layer”. The insulating layer 42A is an example of a “fifth layer”. Next, holes H3 corresponding to the columnar bodies Ma are formed. Then, the sacrificial materials 112 with which the holes H1 and H2 are filled are removed by etching through the holes H3.

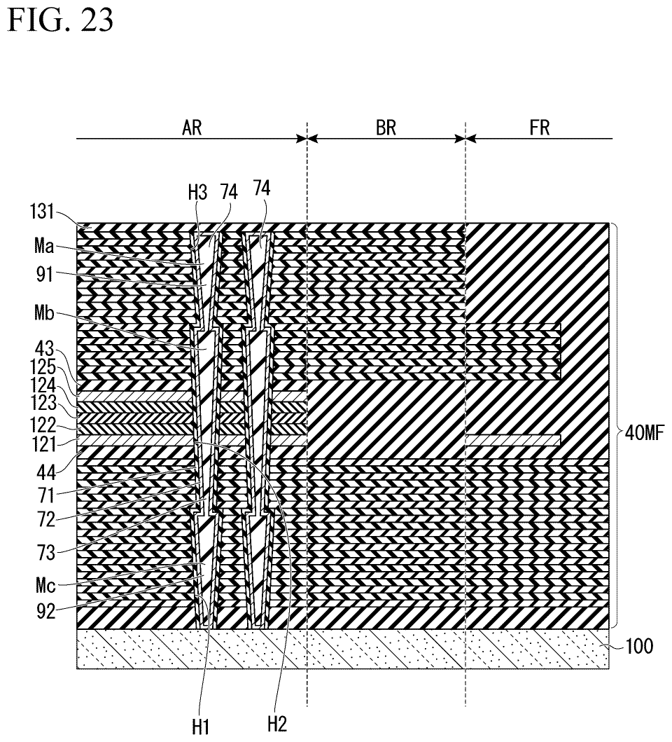

Next, as shown in FIG. 23, the memory film 71, the channel layer 72, and the insulating part 73 are stacked in this order on the inner circumferential surfaces of the holes H1, H2, and H3. Next, the cap part 74 is formed. Therefore, the basic structure of the memory pillar MH is formed. The upper columnar part 92 of the memory pillar MH is an example of a “first-stage columnar part”. The lower columnar part 91 of the memory pillar MH is an example of a “second-stage columnar part”.

Next, an insulating layer 131 is formed on the structure 40ME. The insulating layer 131 is formed by, for example, a film containing silicon and oxygen (for example, a silicon oxide film). Therefore, a structure 40MF is formed.

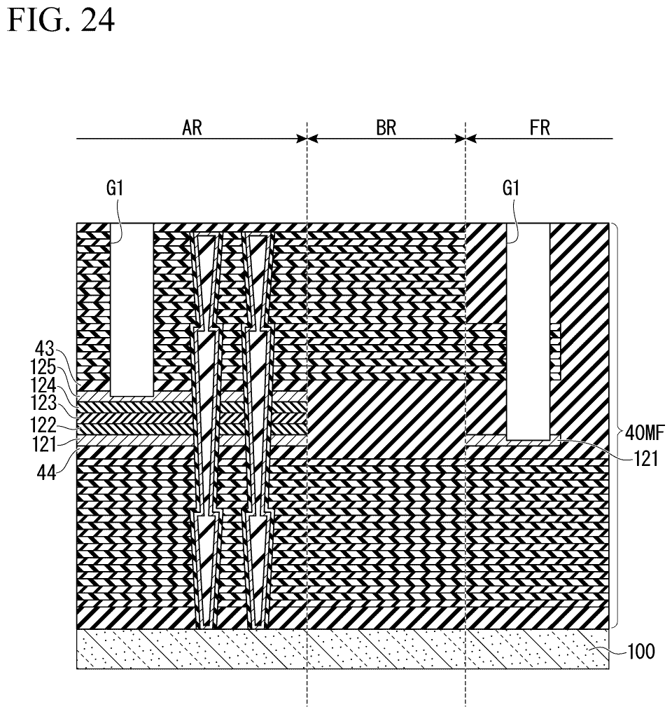

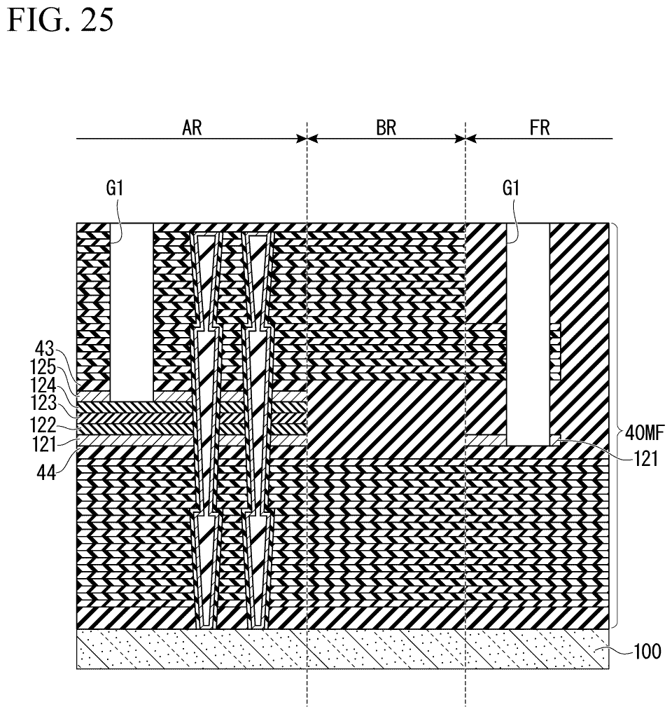

Next, as shown in FIG. 24, a groove G1 is formed in the structure 40MF at a position corresponding to the separation part ST. The groove G1 is a groove extending in the Z direction and the X direction. The groove G1 is formed, for example, using the conductive layer 121 or the conductive layer 125 as a stopper. Next, as shown in FIG. 25, the conductive layer 121 and the conductive layer 125 are removed at the bottom of the groove G1 by etching. Therefore, the sacrificial layer 124 is exposed at the bottom of the groove G1 in the array region AR.

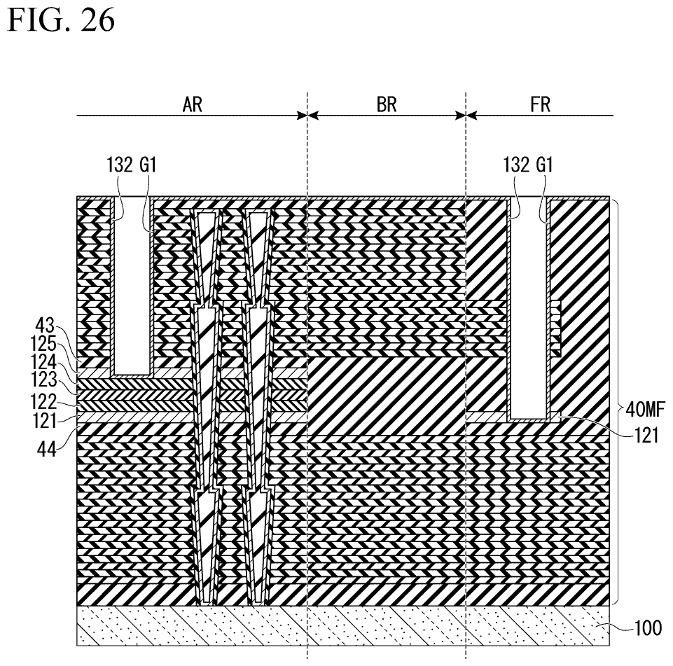

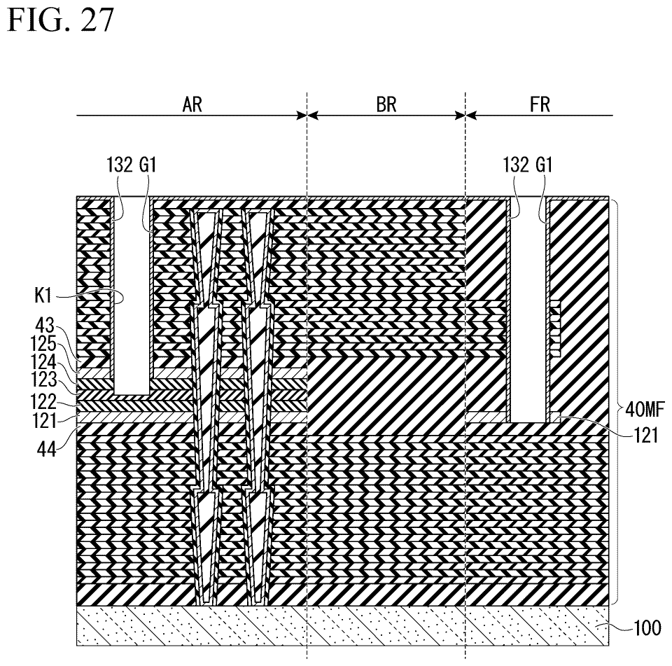

Next, as shown in FIG. 26, a semiconductor film 132 is formed on the inner surface of the groove G1. The semiconductor film 132 is formed of, for example, amorphous silicon. Next, as shown in FIG. 27, the bottom of the semiconductor film 132 and a part of the sacrificial layer 124 are removed while using the semiconductor film 132 as a protective film to protect a second sacrificial layer 112B and a second insulating layer 42B. Therefore, an opening K1 reaching the sacrificial layer 123 is formed.

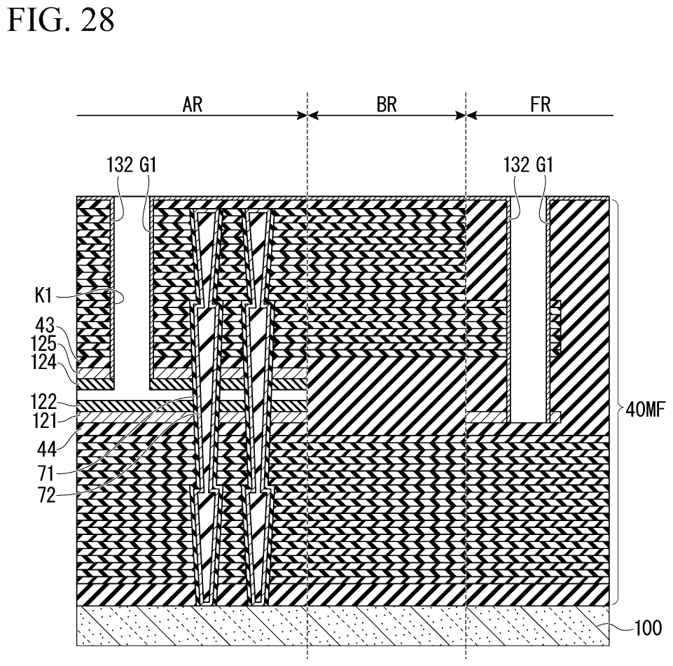

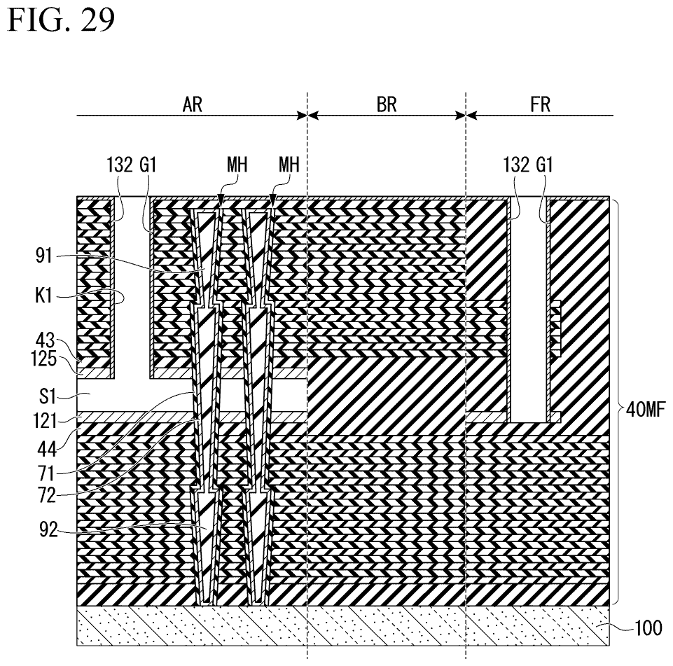

Next, as shown in FIG. 28, an etchant (for example, hot phosphoric acid) capable of removing a silicon nitride film is supplied to the opening K1 to remove the sacrificial layer 123. Next, as shown in FIG. 29, an etchant capable of removing a silicon oxide film is supplied to the opening K1 to remove the sacrificial layers 122 and 124, and the memory film 71 exposed in a space S1 between the conductive layers 121 and 125 is removed. Therefore, the channel layer 72 is exposed in the space S1 between the conductive layers 121 and 125. Therefore, the memory pillar MH is completed.

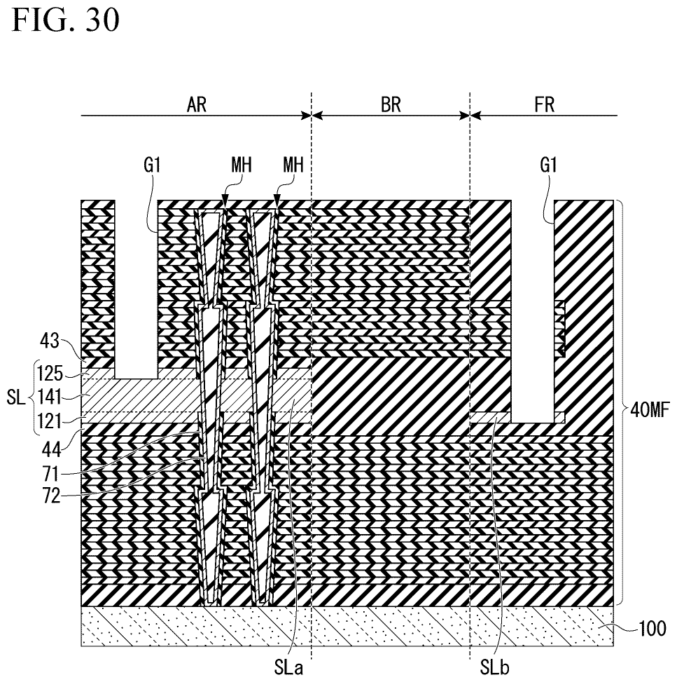

Next, as shown in FIG. 30, the insulating layer 131 is removed. Next, a conductive layer 141 is formed in the space S1 between the conductive layers 121 and 125 through the groove G1. The conductive layer 141 is formed of polysilicon doped with impurities. The conductive layer 141 is connected to the channel layer 72 of the memory pillar MH. The conductive layer 141 is integrated with the conductive layers 121 and 125. Therefore, the conductive layers 121, 125, and 141 form the source line SL.

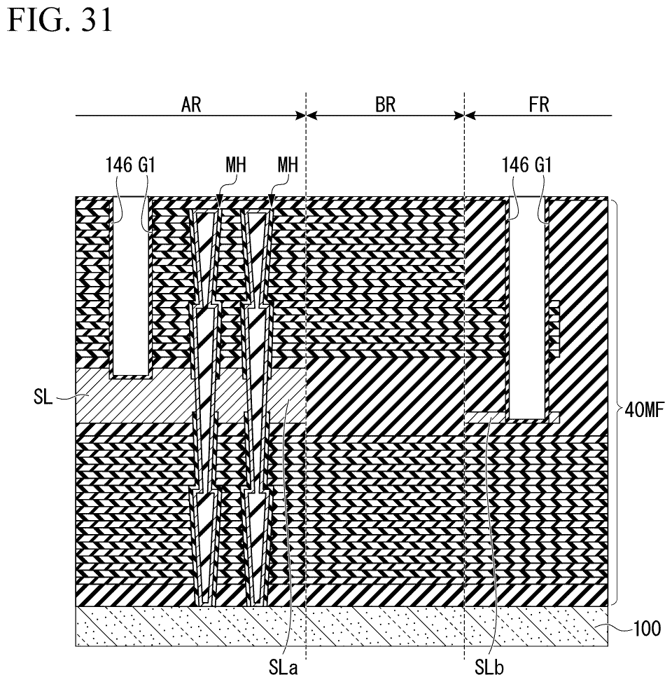

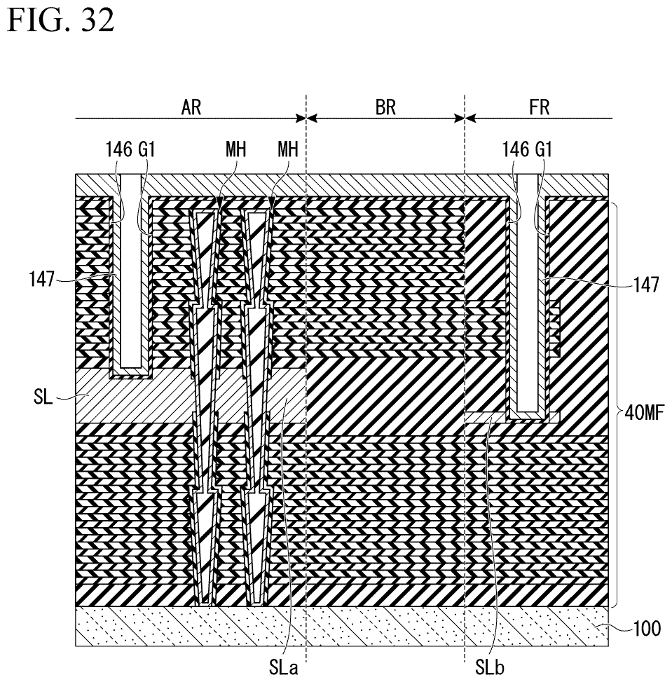

Next, as shown in FIG. 31, an insulating film 146 is formed on the inner surface of the groove G1 as a protective film. The insulating film 146 is formed by, for example, a film containing silicon and oxygen (for example, a silicon oxide film). Next, as shown in FIG. 32, a mask 147 is formed on the inner surface of the insulating film 146. The mask 147 is formed of, for example, a metal material such as titanium nitride or tungsten.

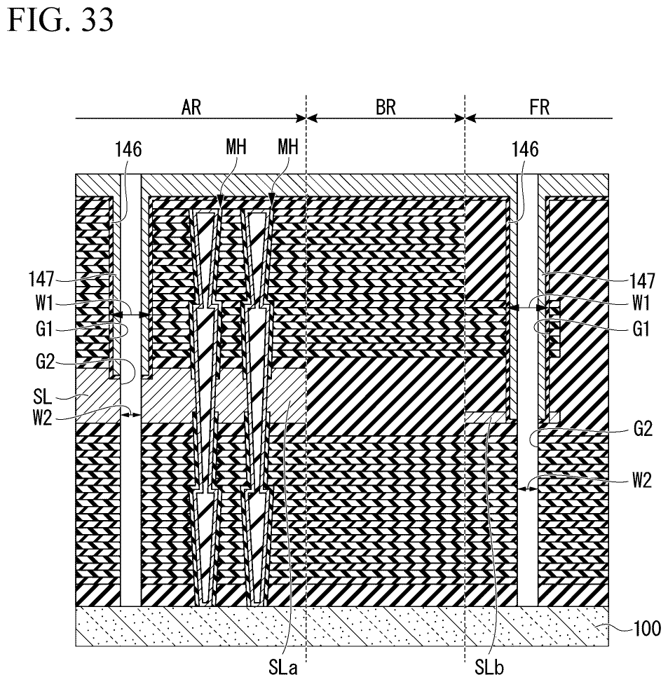

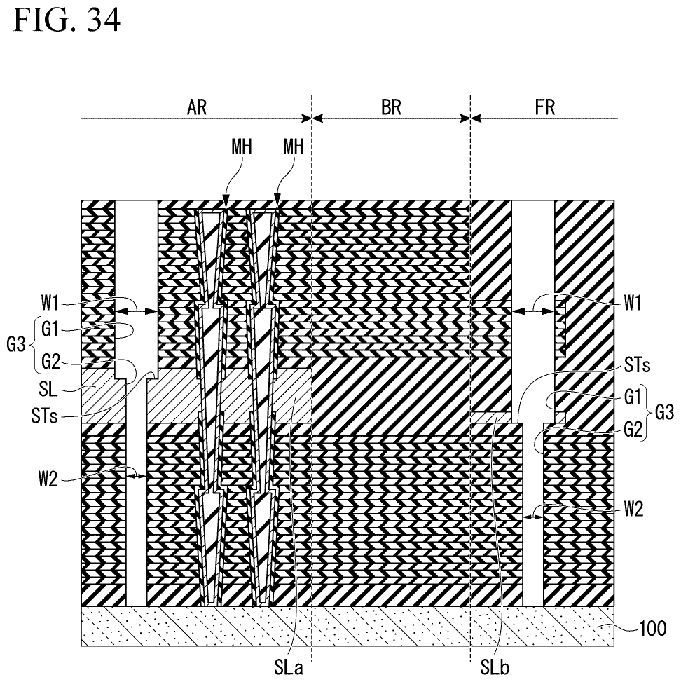

Next, as shown in FIG. 33, a groove G2 is formed. The groove G2 penetrates the mask 147 and the insulating film 146 at the bottom of the groove G1 and penetrates the structure 40MF in the Z direction. Here, since the mask 147 and the insulating film 146 are provided on the inner surface of the groove G1, the width of the groove G2 in the Y direction is smaller than the width of the groove G1 in the Y direction by the thickness corresponding to the mask 147 and the insulating film 146. Next, as shown in FIG. 34, the insulating film 146 and the mask 147 are removed. Therefore, a groove G3 having a step Ts in the middle of the source line SL in the Z direction is formed by the groove G1 and the groove G2.

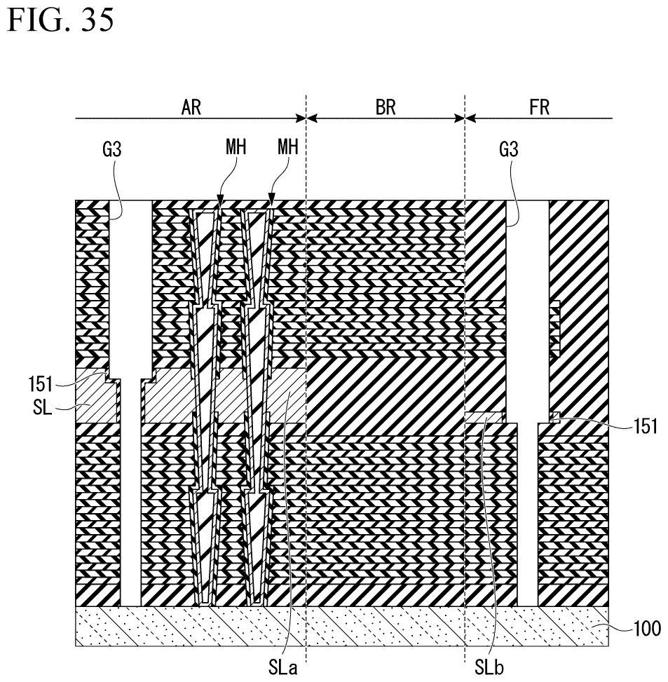

Next, as shown in FIG. 35, an insulating film 151 is formed in a part corresponding to the source line SL on the inner surface of the groove G3. The insulating film 151 is formed by, for example, a film containing silicon and oxygen (for example, a silicon oxide film). The insulating film 151 is formed, for example, by oxidizing the surface of the source line SL. The insulating film 151 is a protective film that protects the source line SL in a replacement process to be described later.

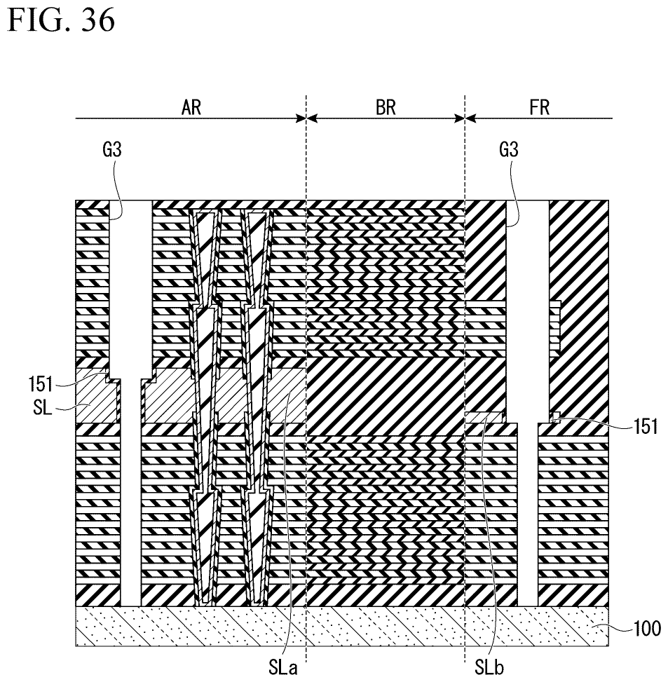

Next, as shown in FIG. 36, an etchant (for example, hot phosphoric acid) capable of removing a silicon nitride film is supplied to the groove G3. Therefore, the plurality of first sacrificial layers 111A and the plurality of second sacrificial layers 111B are removed. At this time, the bit line tap region BR is located far from the groove G3, and thus the etchant does not reach it easily. For this reason, in the bit line tap region BR, the plurality of first sacrificial layers 111A and the plurality of second sacrificial layers 111B remain as the plurality of insulating layers 46A and the plurality of insulating layers 46B.

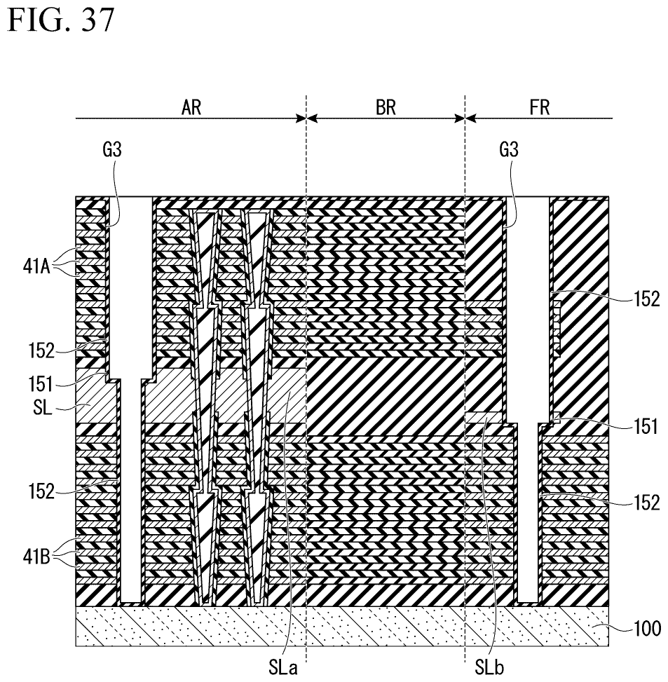

Next, as shown in FIG. 37, a conductive material is supplied through the groove G3 to the space from which the plurality of first sacrificial layers 111A and the plurality of second sacrificial layers 111B have been removed. Therefore, the plurality of first gate electrode layers 41A and the plurality of second gate electrode layers 41B are formed. Next, an insulating film 152 is formed on the inner surface of the groove G3. The insulating film 152 is formed by, for example, a film containing silicon and oxygen (for example, a silicon oxide film).

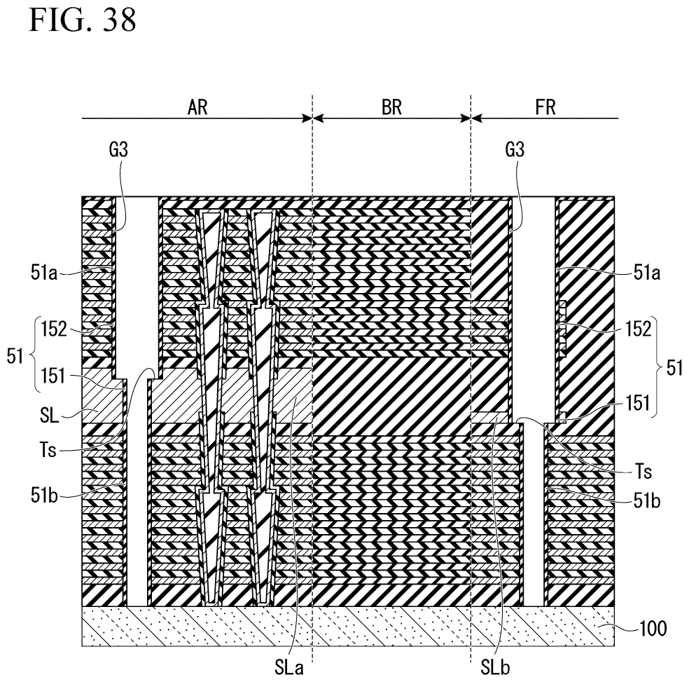

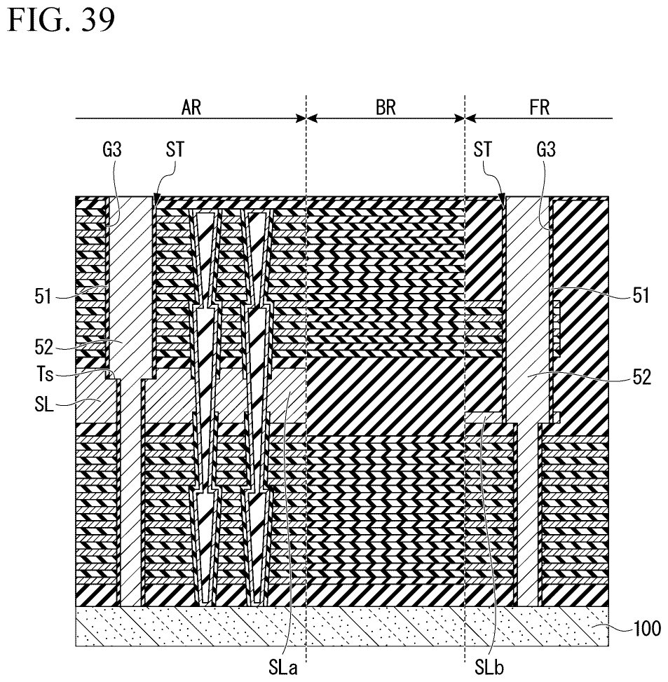

Next, as shown in FIG. 38, the insulating film 151 (part of the insulating film 151 in the X-direction and Y-direction) which exists in the step Ts of the groove G3 is removed by reactive ion etching (RIE). Therefore, the source line SL is exposed in the step Ts of the groove G3. In this embodiment, the insulating film 51 of the separation part ST is formed by the insulating film 151 and the insulating film 152. Next, as shown in FIG. 39, a conductive material is supplied into the groove G3. Therefore, the conductive layer 52 is formed. Therefore, the separation part ST is formed.

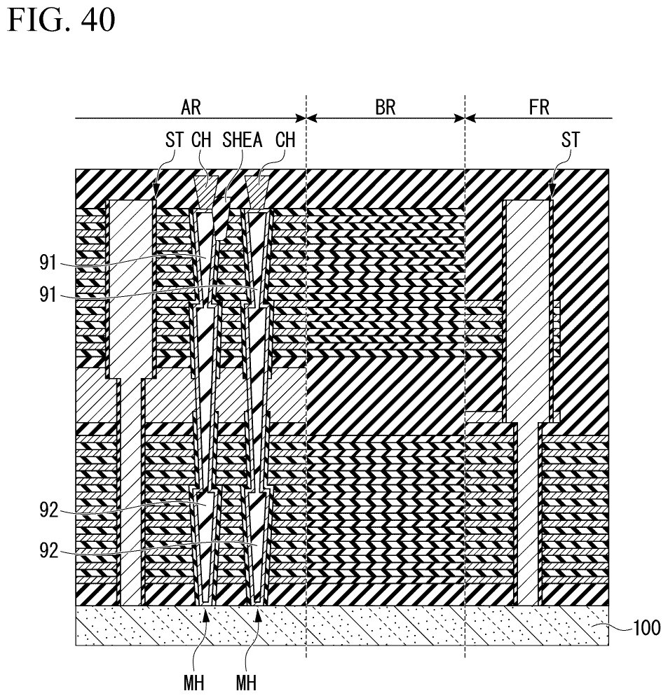

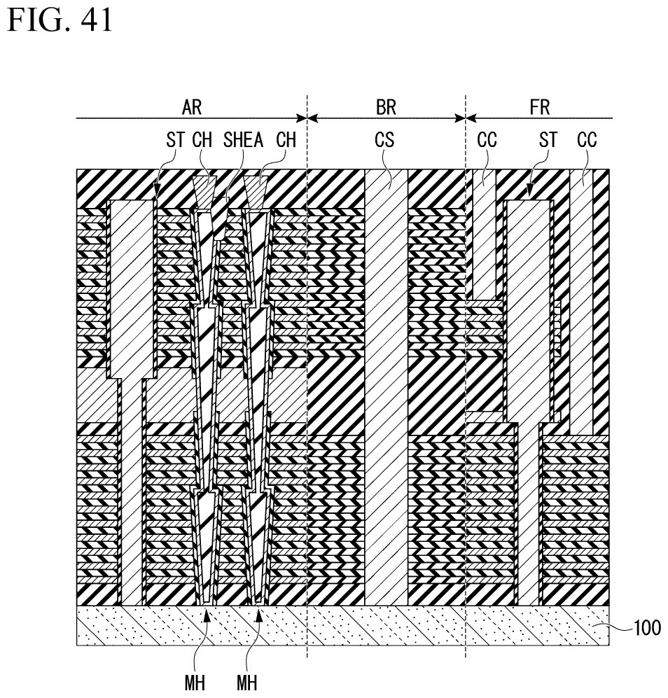

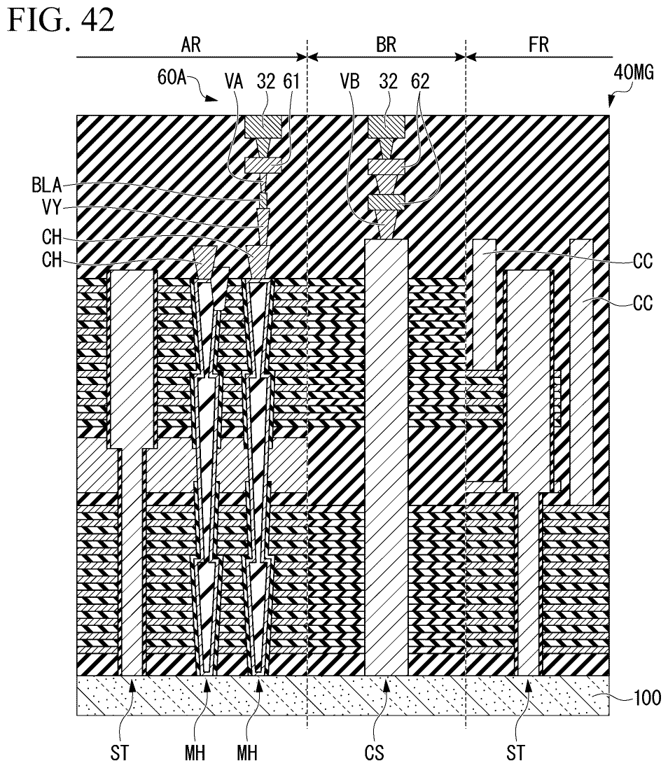

Next, as shown in FIG. 40, the separation part SHEA and the contact CH are formed. The contact CH is in contact with the lower columnar part 91 of the memory pillar MH. Next, as shown in FIG. 41, the contact CS is formed in the bit line tap region BR, and the contact CC is formed in the hook-up region FR. Next, as shown in FIG. 42, the contact VY, the bit line BLA, and the wiring part 60A are formed. Therefore, a structure 40 MG serving as the basic structure of the second chip 3 is formed.

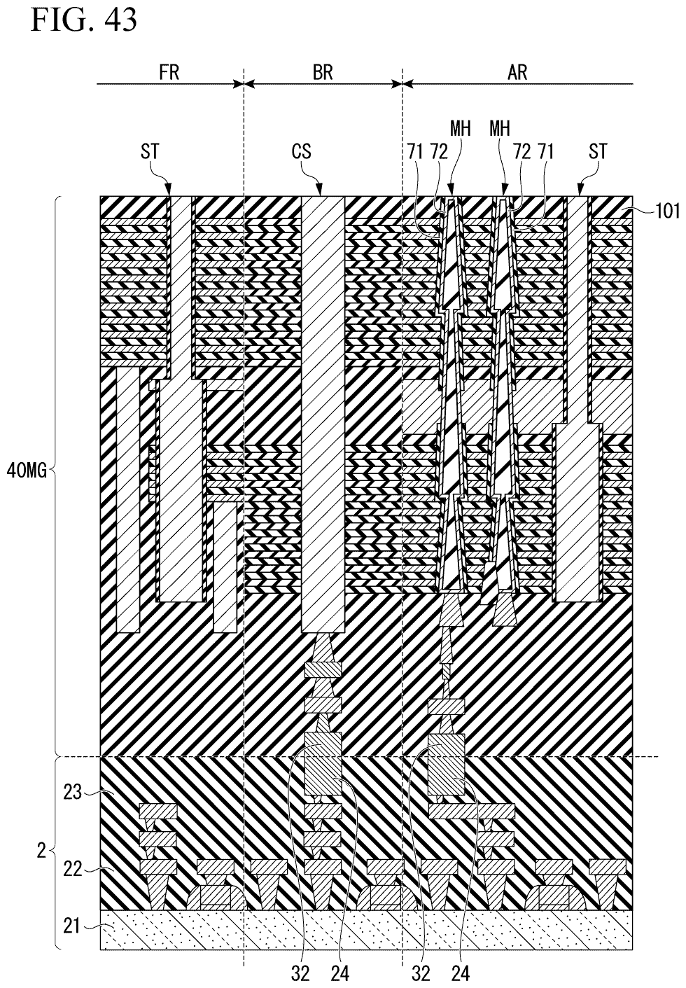

Next, as shown in FIG. 43, the structure 40 MG is turned upside down, and the first chip 2, which is prepared separately, and the structure 40 MG are bonded together. Next, the semiconductor substrate 100 is removed. Next, the memory film 71 is removed from the upper end part of the memory pillar MH, and the channel layer 72 is exposed.

Note that, at this stage, a process of thickening the upper end part of the channel layer 72 may be additionally performed.

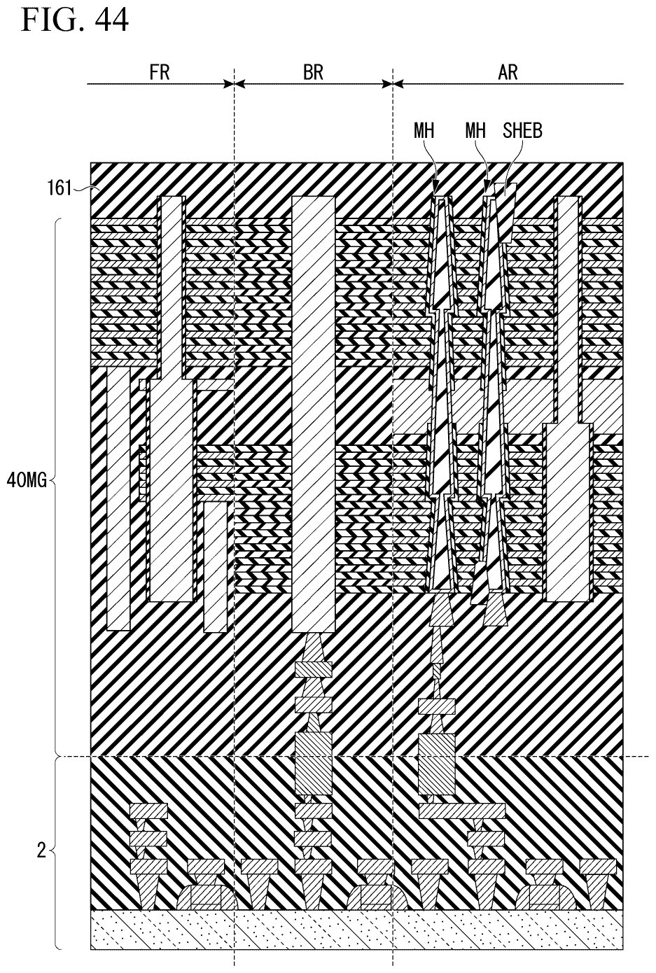

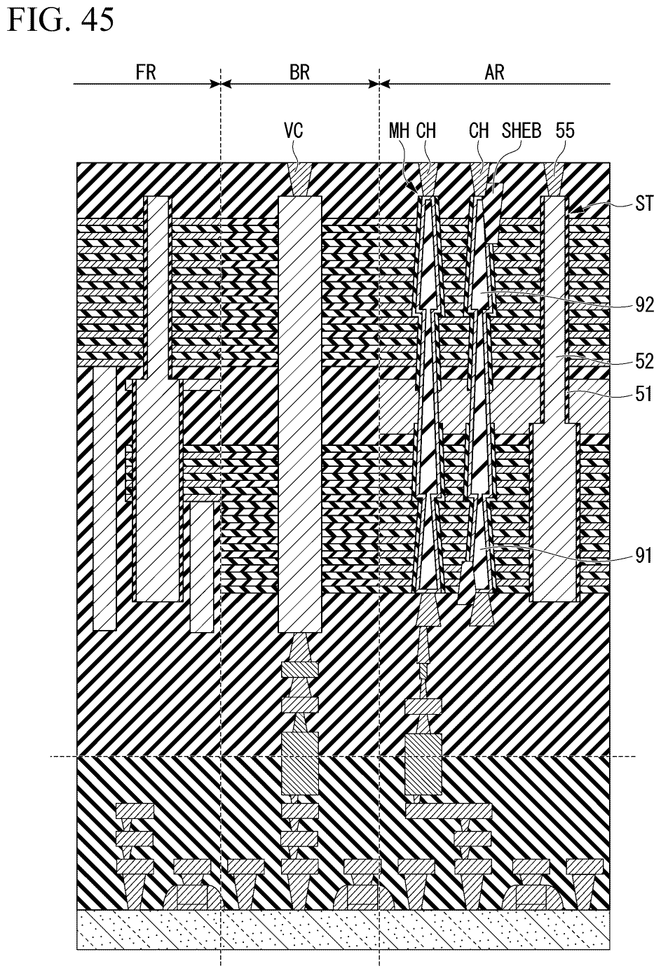

Next, as shown in FIG. 44, an insulating part 161 is formed on the structure 40 MG. Next, the separation part SHEB is formed. Next, as shown in FIG. 45, the contact CH and the contact 55 are formed. The contact CH is in contact with the upper columnar part 92 of the memory pillar MH. The contact 55 is in contact with the separation part ST.

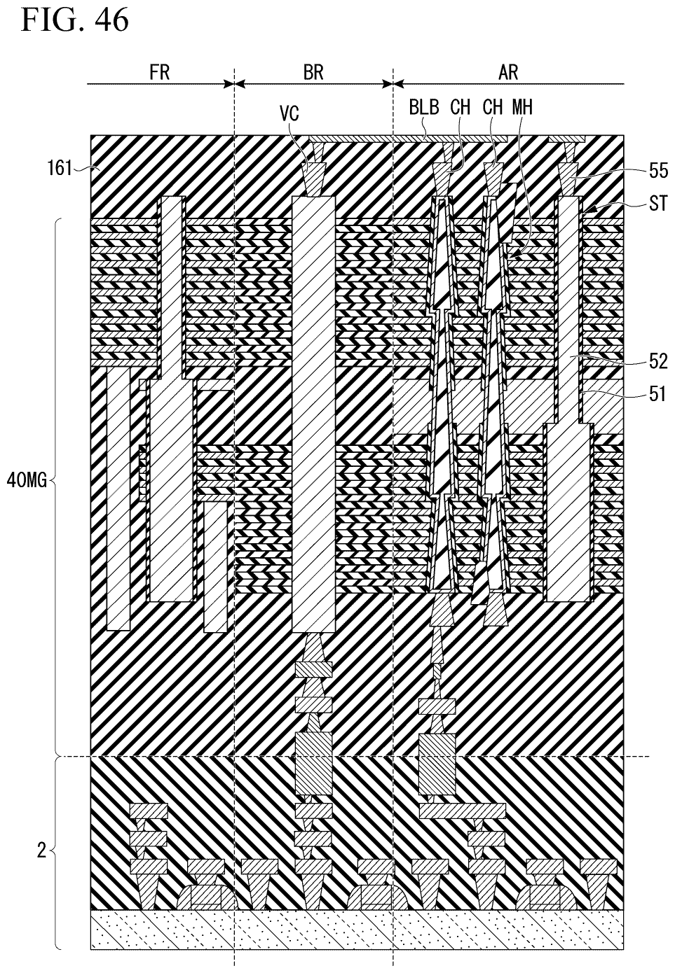

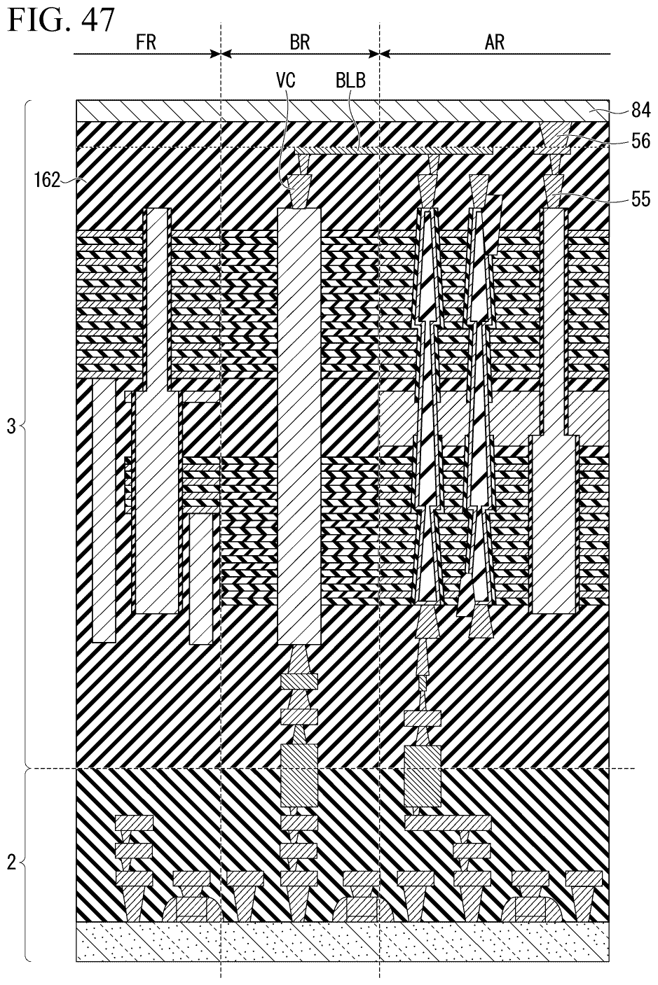

Next, as shown in FIG. 46, the upper bit line BLB is formed. Next, as shown in FIG. 47, an insulating part 162 that covers the upper bit line BLB is formed. Next, an electrical connection line 84 electrically connected to the source line SL via the separation part ST is formed on the insulating part 162. Next, an insulating part that covers the electrical connection line 84 is formed. Therefore, the semiconductor storage device 1 is completed.

### A9. Advantages

In recent years, the number of gate electrode layers stacked has tended to increase as the capacity of semiconductor storage devices has increased. As the number of gate electrode layers stacked increases, the resistance of the string STR increases, it is difficult to ensure a current flowing through the channel layer of the memory pillar.

On the other hand, in this embodiment, the semiconductor storage device 1 includes the first multi-layered body 40A, the second multi-layered body 40B, the source line SL, the lower columnar part 91, the upper columnar part 92, the lower bit line BLA, and the upper bit line BLB. The source line SL is disposed between the first multi-layered body 40A and the second multi-layered body 40B in the Z direction. The lower columnar part 91 extends in the Z direction within the first multi-layered body 40A. The lower columnar part 91 includes the memory film 71A including the charge storage part 82a, and the lower semiconductor film 72A. The upper columnar part 92 extends in the Z direction within the second multi-layered body 40B. The upper columnar part 92 includes the memory film 71B including the charge storage part 82a, and the upper semiconductor film 72B. The lower bit line BLA is disposed on a side of the first multi-layered body 40A opposite to the source line SL. The lower first bit line BLA is electrically connected to the lower columnar part 91. The upper bit line BLB is disposed on a side of the second multi-layered body 40B opposite to the source line SL. The upper bit line BLB is electrically connected to the upper columnar part 92.

According to such a configuration, for example, as compared with the case in which the source line SL is provided on the side in the +Z direction of the first multi-layered body 40A and the second multi-layered body 40B, the resistance of the string STR becomes smaller, and it is easy to ensure a current flowing through the channel layer 72. When it becomes to easier to ensure the current flowing through the channel layer 72, it is possible to achieve an improvement in the reliability of a write operation of the semiconductor storage device 1. Therefore, it is possible to provide the semiconductor storage device 1 capable of achieving an improvement in electrical characteristics.

In this embodiment, the lower columnar part 91 and the upper columnar part 92 overlap each other when viewed from the Z direction. According to such a configuration, the lower columnar part 91 and the upper columnar part 92 can be disposed more densely in the semiconductor storage device 1. Therefore, it becomes easier to achieve a further increase in the capacity of the semiconductor storage device 1. In this embodiment, the semiconductor storage device 1 includes the memory pillar MH. The memory pillar MH includes the lower columnar part 91 and the upper columnar part 92. The memory pillar MH penetrates the first multi-layered body 40A, the second multi-layered body 40B, and the source line SL in the Z direction. With such a configuration, the lower columnar part 91 and the upper columnar part 92 can be formed by one memory pillar MH. Therefore, it is possible to improve the manufacturability of the semiconductor storage device 1 as compared with the case in which the lower columnar part 91 and the upper columnar part 92 are formed by separate memory pillars MH.

In this embodiment, the memory film 71 of the lower columnar part 91 and the memory film 71 of the upper columnar part 92 are separated from each other in the Z direction. The memory pillar MH includes the memory film 71 of the lower columnar part 91, the memory film 71 of the upper columnar part 92, and the channel layer 72.

The channel layer 72 is connected to the source line SL in a region between the memory film 71 of the lower columnar part 91 and the memory film 71 of the upper columnar part 92. With such a configuration, it is possible to ensure electrical connection between the memory pillar MH and the source line SL in the middle of the memory pillar MH in the Z direction.

In this embodiment, the number of gate electrode layers 41A included in the first multi-layered body 40A is different from the number of gate electrode layers 41B included in the second multi-layered body 40B. With such a configuration, the capacity of the block BLKA included in the first multi-layered body 40A can be made different from the capacity of the block BLKB included in the second multi-layered body 40B.

Since the capacity of the block BLKA included in the first multi-layered body 40A can be made different from the capacity of the block BLKB included in the second multi-layered body 40B, it is possible to perform a more appropriate write operation and the like. For example, the capacity of the block BLKA can be made smaller than that of the block BLKB, and data with a smaller data size is written to the block BLKA in preference to the block BLKB, thereby making it possible to achieve in the speed of the write operation.

In this embodiment, the semiconductor storage device 1 includes the sense amplifier module 17 having the terminal 17t, and the switching circuit 19. The switching circuit 19 can switch between a first state and a second state. The first state is a state in which the terminal 17t of the sense amplifier module 17 is electrically connected to the lower bit line BLA. The second state is a state in which the terminal 17t of the sense amplifier module 17 is electrically connected to the upper bit line BLB. With such a configuration, it is possible to reduce power consumption associated with switching of a write target, compared with, for example, switching of a write target between the first multi-layered body 40A and the second multi-layered body 40B using the drain-side select gate lines SGDA and SGDB.

In this embodiment, the semiconductor storage device 1 includes the contact CS. The contact CS is provided between the memory pillar MHA and the memory pillar MHC. The contact CS extends in the Z direction and electrically connects the switching circuit 19 (or the sense amplifier module 17) and the upper bit line BLB. With such a configuration, it is possible to reduce an electrical connection path between the switching circuit 19 (or the sense amplifier module 17) and the upper bit line BLB. Therefore, it is possible to achieve an improvement in the processing speed of the semiconductor storage device 1 or a reduction in power consumption.

In this embodiment, the semiconductor storage device 1 includes the separation part ST. The separation part ST includes the first part STa that separates each of the plurality of gate electrode layers 41A in the Y direction, and the second part STb that separates each of the plurality of gate electrode layers 41B in the Y direction. The separation part ST includes the conductive layer 52 and the insulating film 51 that covers the conductive layer 52. The conductive layer 52 and the insulating film 51 are provided over the first part STa and the second part STb. The width W1 of the first part STa in the Y direction is larger than the width W2 of the second part STb in the Y direction. A boundary between the first part STa and the second part STb is located inside the source line SL and has the step Ts in the Y direction. In the step Ts, the insulating film 51 is separated in the Y direction, and the conductive layer 52 is exposed to the outside of the insulating film 51 and connected to the source line SL.

With such a configuration, an electrical connection path connected to the source line SL can be provided inside the array region AR. With such a configuration, it becomes easier to improve the electrical characteristics of the semiconductor storage device 1 as compared with the case in which the electrical connection path is provided in the hook-up region FR. For example, according to the above configuration, at least one of the following effects can be obtained.
The number of electrical connection paths can be increased as compared with the case in which the electrical connection path is provided in the hook-up region FR.
The resistance of the electrical connection path with respect to the source line SL can be reduced.
The length of a path between the electrical connection path and each memory pillar MH can be reduced.

### A9. Modified Example

Hereinafter, several modified examples of the first embodiment will be described. Note that, these modified examples may be applied to a second embodiment to be described later.

In the semiconductor storage device 1 according to the first embodiment mentioned above, the switching circuit 19 is provided, and the switching circuit 19 switches between the lower bit line BLA and the upper bit line BLB. In a modified example, instead of such a configuration, the switching circuit 19 may not be provided. In this case, the switching between the lower bit line BLA and the upper bit line BLB may be performed, for example, using the drain-side select gate line SGDA of the first multi-layered body 40A and the drain-side select gate line SGDB of the second multi-layered body 40B.

In the semiconductor storage device 1 according to the first embodiment mentioned above, electrical connection between the source line SL and the electrical connection line 64 is ensured by the conductive layer 52 of the separation part ST.

Alternatively, the conductive layer 52 of the separation part ST may be omitted. In this case, the contact CC for electrically connecting the source line SL and the electrical connection line 64 may be provided in the hook-up region FR.

### Second Embodiment

Next, a semiconductor storage device 1A according to a second embodiment will be described. The second embodiment is different from the first embodiment in that a lower columnar part 91 and an upper columnar part 92 are formed by separate memory pillars. Note that, configurations other than the configurations described below are the same as those in the first embodiment.

### B1. Memory Pillar

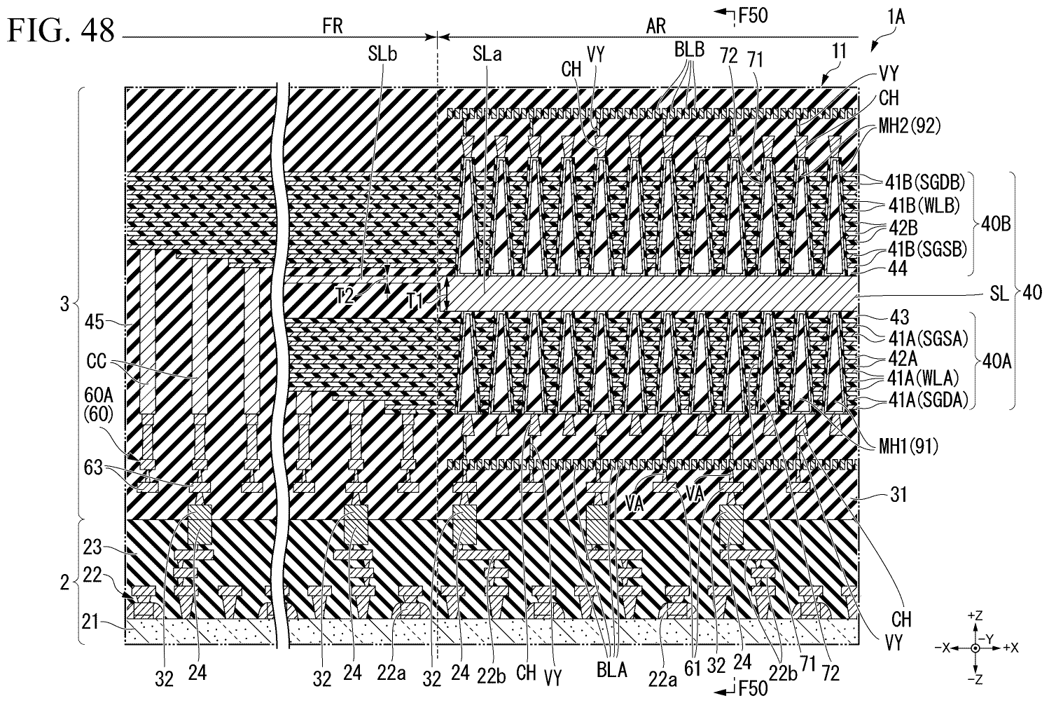

FIG. 48 is a cross-sectional view showing a part of the semiconductor storage device 1A according to the second embodiment. In this embodiment, the semiconductor storage device 1A includes a plurality of first memory pillars MH1 and a plurality of second memory pillars MH2 instead of the plurality of memory pillars MH in the first embodiment.

### First Memory Pillar

The plurality of first memory pillars MH1 are arranged in the X direction and the Y direction. The first memory pillars MH1 extend in the Z direction within the first multi-layered body 40A. The first memory pillars MH1 penetrate the first multi-layered body 40A in the Z direction. In this embodiment, the total length of the lower columnar part 91 in the Z direction is formed by the total length of the first memory pillars MH1 in the Z direction. The lower columnar part 91 is an example of a “first columnar part”. Note that, the first memory pillar MH1 is not limited to a single-stage memory pillar in the Z direction, but may be a two-stage or higher-stage memory pillar in which a plurality of columnar bodies are stacked in the Z direction.

### Second Memory Pillar

The plurality of second memory pillars MH2 are arranged in the X direction and the Y direction. The second memory pillars MH2 extend in the Z direction within the second multi-layered body 40B. The second memory pillars MH2 penetrate the second multi-layered body 40B in the Z direction. In this embodiment, the total length of the upper columnar part 92 in the Z direction is formed by the total length of the second memory pillars MH2 in the Z direction. The second memory pillar MH2 is an example of a “second columnar part”. Note that, the second memory pillar MH2 is not limited to a single-stage memory pillar in the Z direction, but may be a two-stage or higher-stage memory pillar in which a plurality of columnar bodies are stacked in the Z direction.

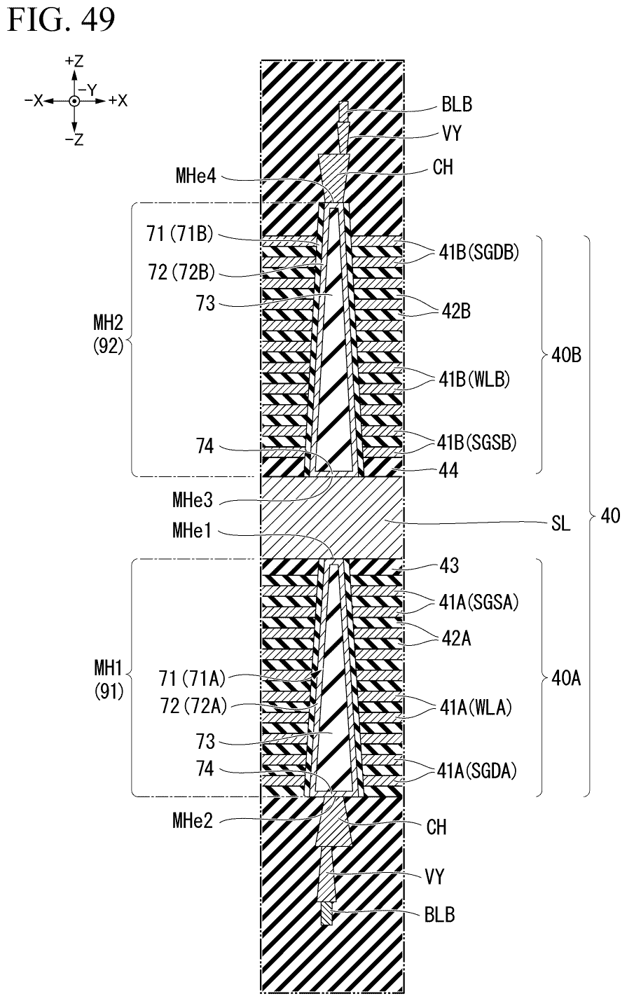

FIG. 49 is a cross-sectional view showing the memory pillars MH1 and MH2 according to the second embodiment. The first memory pillar MH1 (lower columnar part 91) includes the memory film 71 (lower memory film 71A), the channel layer 72 (lower semiconductor film 72A), the insulating part 73, and the cap part 74. The memory film 71 included in the first memory pillar MH1 is an example of a “first memory film”. The channel layer 72 included in the first memory pillar MH1 is an example of a “first semiconductor film.”

The first memory pillar MH1 does not penetrate the source line SL. The upper end of the first memory pillar MH1 is physically and electrically connected to the source line SL. The contact CH is in contact with the lower end of the first memory pillar MH1 from the side in the −Z direction. The channel layer 72 of the first memory pillar MH1 is electrically connected to the lower bit line BLA via the contact CH and the contact VY. In this embodiment, the circumference (diameter) of the first memory pillar MH1 (lower columnar part 91) in the cross-section in the X direction and the Y direction gradually increases in a direction from the upper side to the lower side.

The first memory pillar MH1 includes a first end MHe1 (end on the side in the +Z direction) which is in contact with the source line SL, and a second end MHe2 (end on the side in the −Z direction) which is located on a side opposite to the first end MHe1. The second end MHe2 is in contact with the contact CH. The second end MHe2 is electrically connected to the bit line BLA via the contact CH. In this embodiment, the circumference (diameter) of the first memory pillar MH1 at the second end MHe2 is larger than the circumference (diameter) of the first memory pillar MH1 at the first end MHe1.

The second memory pillar MH2 (upper columnar part 92) includes the memory film 71 (upper memory film 71B), the channel layer 72 (upper semiconductor film 72B), the insulating part 73, and the cap part 74. The memory film 71 included in the second memory pillar MH2 is an example of a “second memory film”. The channel layer 72 included in the second memory pillar MH2 is an example of a “second semiconductor film”.

The second memory pillar MH2 does not penetrate the source line SL. The lower end of the second memory pillar MH2 is physically and electrically connected to the source line SL. The upper end of the second memory pillar MH2 is in contact with the contact CH from the side in the +Z direction. The channel layer 72 of the second memory pillar MH2 is electrically connected to the upper bit line BLB via the contact CH and the contact VY. In this embodiment, the circumference (diameter) of the second memory pillar MHB in the cross-section in the X direction and the Y direction of the second memory pillar MH2 (upper columnar part 92) gradually increases as the second memory pillar MH2 moves from the upper side to the lower side.

The second memory pillar MH2 includes a third end MHe3 (end on the side in the −Z direction) which is in contact with the source line SL, and a fourth end MHe4 (end on the side in the +Z direction) which is located on a side opposite to the third end MHe3. The fourth end MHe4 is in contact with the contact CH. The fourth end MHe4 is electrically connected to the bit line BLB via the contact CH. In this embodiment, the circumference (diameter) of the second memory pillar MH2 at the fourth end MHe4 is smaller than the circumference (diameter) of the second memory pillar MH2 at the third end MHe3.

In this embodiment, the second memory pillar MH2 is separated from the first memory pillar MH1 in the Z direction. The first memory pillar MH1 and the second memory pillar MH2 are separated from each other. For example, the channel layer 72 (lower semiconductor film 72A) included in the first memory pillar MH1 and the channel layer 72 (upper semiconductor film 72B) included in the second memory pillar MH2 are separated from each other in the Z direction. Each of the channel layer 72 (lower semiconductor film 72A) included in the first memory pillar MH1 and the channel layer 72 (upper semiconductor film 72B) included in the second memory pillar MH2 is electrically connected to the source line SL. The channel layer 72 included in the first memory pillar MH1 and the channel layer 72 included in the second memory pillar MH2 are electrically connected to each other via the source line SL.

### B2. Separation Part

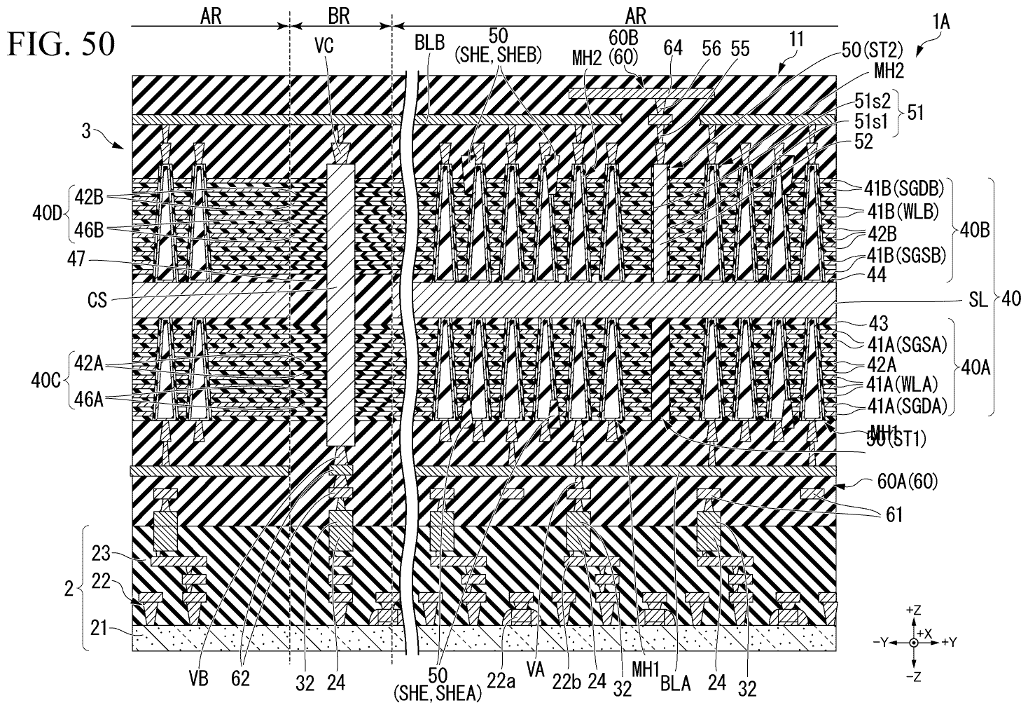

FIG. 50 is a cross-sectional view showing the semiconductor storage device 1A shown in FIG. 48 taken along line F50-F50. In this embodiment, the semiconductor storage device 1A includes a first separation part ST1 and a second separation part ST2 instead of the separation part ST of the first embodiment.

### First Separation Part

The first separation part ST1 is a wall part extending in the Z direction and the Y direction. The first separation part ST1 extends in the Z direction within the first multi-layered body 40A. The first separation part ST1 penetrates the first multi-layered body 40A in the Z direction. The first separation part ST1 separates all of the gate electrode layers 41 included in the first multi-layered body 40A in the Y direction. The first separation part ST1 does not penetrate the source line SL. In the example shown in FIG. 50, the first separation part ST1 does not include the conductive layer 52 and is formed only by the insulating film 51. Note that, instead of the above example, the first separation part ST1 may include the insulating film 51 and the conductive layer 52.

### Second Separation Part

The second separation part ST2 is a wall part extending in the Z direction and the Y direction. The second separation part ST2 extends in the Z direction within the second multi-layered body 40B. The second separation part ST2 penetrates the second multi-layered body 40B in the Z direction. The second separation part ST2 separates all of the gate electrode layers 41 included in the second multi-layered body 40B in the Y direction. In this embodiment, the second separation part ST2 does not penetrate the source line SL. In this embodiment, the second separation part ST2 is separated from the first separation part ST1 in the Z direction. In the example shown in FIG. 50, the second separation part ST2 includes the insulating film 51 and the conductive layer 52.

Alternatively, when the first separation part ST1 includes the conductive layer 52, the second separation part ST2 may be formed only by the insulating film 51 without including the conductive layer 52.

### B3. Manufacturing Method

Next, a method of manufacturing the semiconductor storage device 1A will be described.

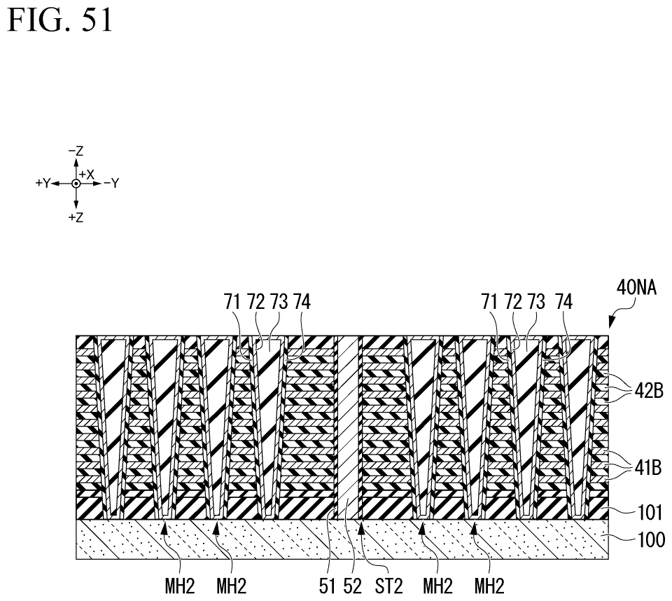

FIGS. 51 to 56 are diagrams showing a method of manufacturing the semiconductor storage device 1A. First, as shown in FIG. 51, the insulating layer 101 is formed on the semiconductor substrate 100. Next, the sacrificial layers 111B and the insulating layers 42B are alternately stacked in the Z direction. Next, the ends of the plurality of sacrificial layers 111B are formed in a stepped shape. In addition, the second memory pillar MH2 and the second separation part ST2 are formed. Next, the plurality of sacrificial layers 111B are replaced with the plurality of gate electrode layers 41B by a replacement process. Therefore, a structure 40NA is formed.

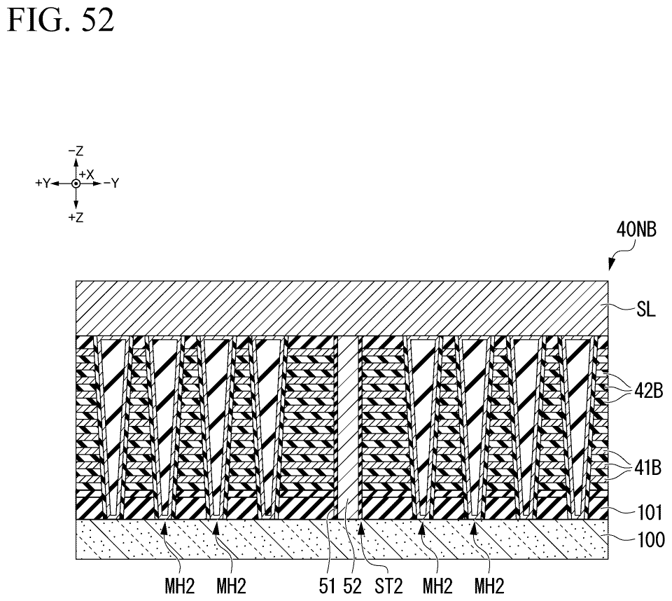

Next, as shown in FIG. 52, the source line SL is provided on the structure 40NA. Therefore, a structure 40NB is formed. The source line SL is an example of a “third layer”.

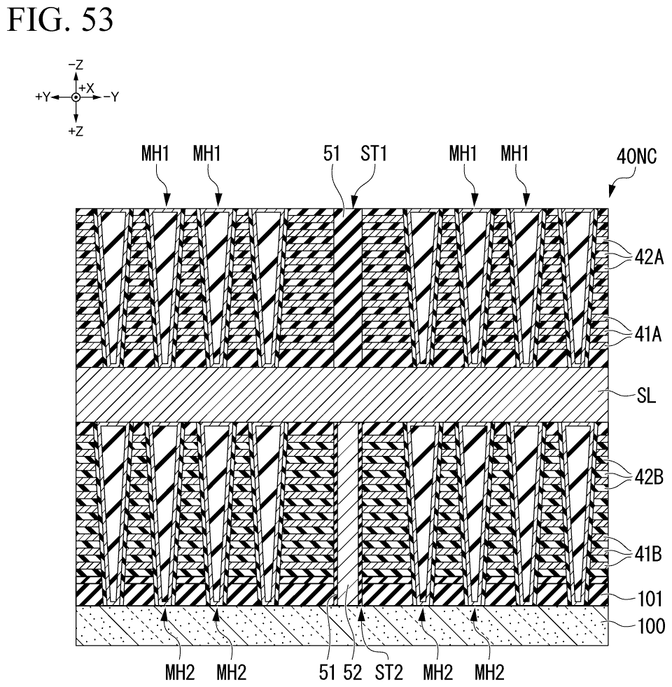

Next, as shown in FIG. 53, the sacrificial layers 111A and the insulating layers 42A are alternately stacked on the structure 40NA in the Z direction. Next, the ends of the plurality of sacrificial layers 111A are formed in a stepped shape. In addition, the first memory pillar MH1 and the first separation part ST1 are provided. Next, the plurality of sacrificial layers 111A are replaced with the plurality of gate electrode layers 41A by a replacement process. Therefore, a structure 40NC is formed.

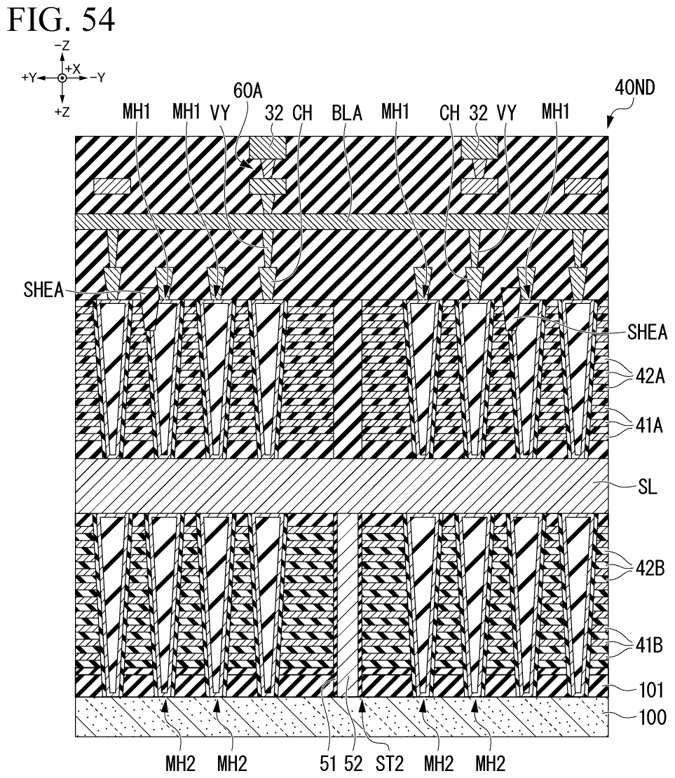

Next, as shown in FIG. 54, the separation parts SHEA, the contacts CH, the contacts VY, the lower bit lines BLA, the pads 32, and the wiring parts 60A are formed. Therefore, a structure 40ND is formed. The structure 40ND includes the basic part of the second chip 3.

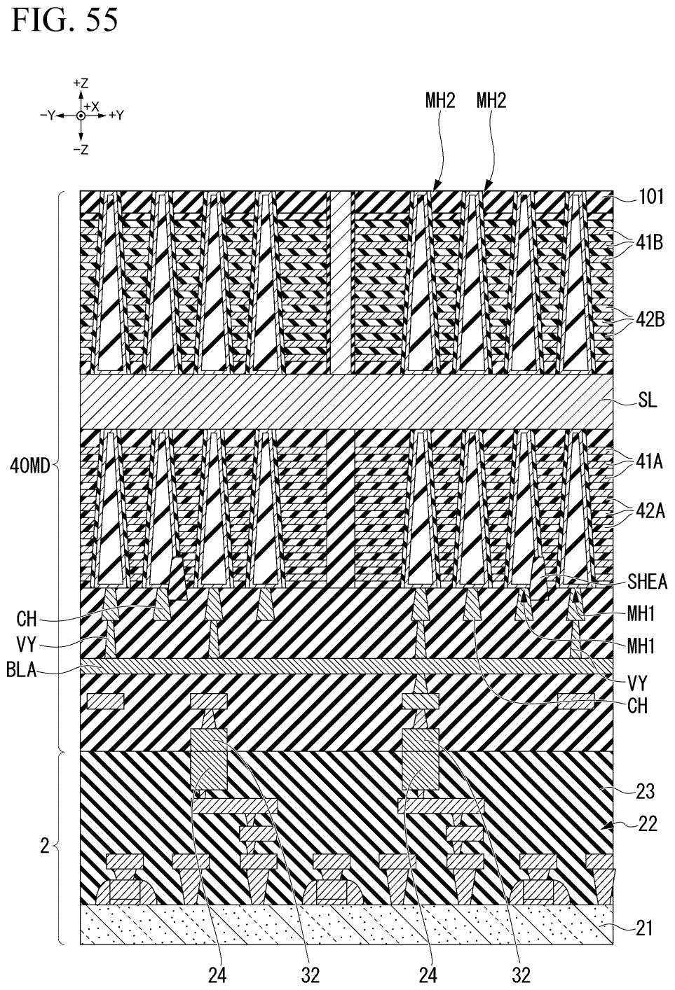

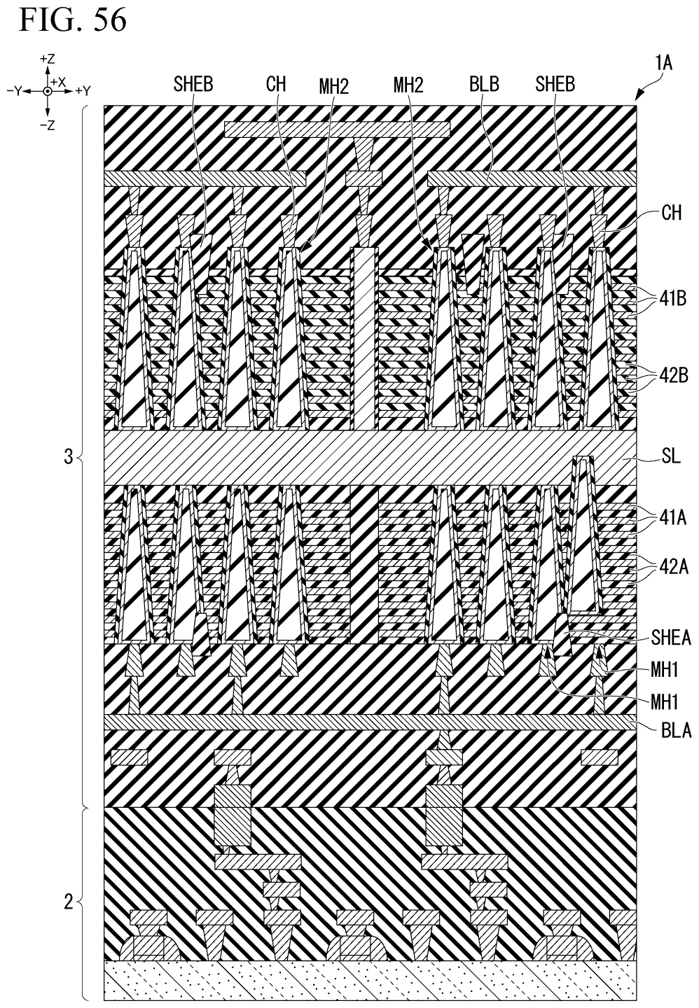

Next, as shown in FIG. 55, the structure 40ND is turned upside down, and the first chip 2, which is prepared separately, and the structure 40ND are bonded together. Next, the semiconductor substrate 100 is removed. Next, as shown in FIG. 56, the upper bit line BLB is formed. Next, the wiring part 60B, an insulating part, and the like are provided. Therefore, the semiconductor storage device 1A is completed.

### B4. Advantages

According to such a configuration, it is possible to achieve an improvement in the electrical characteristics of the semiconductor storage device 1A, as in the first embodiment.

### B5. Modified Example of Manufacturing Method

In the second embodiment mentioned above, a replacement process in which the plurality of sacrificial layers 111B are replaced with the plurality of gate electrode layers 41B is performed before the source line SL is formed. Alternatively, the replacement process in which the plurality of sacrificial layers 111B are replaced with the plurality of gate electrode layers 41B may be performed after the source line SL is formed. For example, the replacement process in which the plurality of sacrificial layers 111B are replaced with the plurality of gate electrode layers 41B may be performed simultaneously with the replacement process in which the plurality of sacrificial layers 111A are replaced with the plurality of gate electrode layers 41A.

Several embodiments and modified examples have been mentioned above. However, the embodiments and the modified examples are not limited to the above examples. For example, the above-described embodiments and modified examples may be implemented in appropriate combinations. In addition, the source line SL may be provided separately for each string STR. The lower bit line BLB and the upper bit line BLB may be electrically connected directly to the sense amplifier module 17 without going through the switching circuit 19.

According to at least one of the embodiments mentioned above, the semiconductor storage device includes a first multi-layered body, a second multi-layered body, a source line, a first columnar part, a second columnar part, a first bit line, and a second bit line. The first multi-layered body includes a plurality of first gate electrode layers and a plurality of first insulating layers. The plurality of first gate electrode layers and the plurality of first insulating layers are alternately stacked one by one in a first direction. The second multi-layered body is disposed on a first side of the first multi-layered body in the first direction. The second multi-layered body includes a plurality of second gate electrode layers and a plurality of second insulating layers. The plurality of second gate electrode layers and the plurality of second insulating layers are alternately stacked one by one in the first direction. The source line is disposed between the first multi-layered body and the second multi-layered body in the first direction. The source line extends in a second direction different from the first direction. The first columnar part extends in the first direction within the first multi-layered body. The first columnar part includes a first memory film including a charge storage part, and a first semiconductor film. The second columnar part extends in the first direction within the second multi-layered body. The second columnar part includes a second memory film including a charge storage part, and a second semiconductor film. The first bit line is disposed on a second side of the first multi-layered body opposite to the first side in the first direction. The first bit line is electrically connected to the first columnar part. The second bit line is disposed on the first side of the second multi-layered body in the first direction. The second bit line is electrically connected to the second columnar part. According to such a configuration, it is possible to achieve an improvement in the electrical characteristics of the semiconductor storage device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a first multi-layered body including a plurality of first gate electrode layers and a plurality of first insulating layers, the plurality of first gate electrode layers and the plurality of first insulating layers being alternately stacked one by one in a first direction;
a second multi-layered body on a first side of the first multi-layered body in the first direction, the second multi-layered body including a plurality of second gate electrode layers and a plurality of second insulating layers, the plurality of second gate electrode layers and the plurality of second insulating layers being alternately stacked one by one in the first direction;
a source line between the first multi-layered body and the second multi-layered body in the first direction, the source line extending in a second direction intersecting the first direction;
a first columnar part extending in the first direction within the first multi-layered body, the first columnar part including a first memory film and a first semiconductor film, the first memory film including a charge storage part;
a second columnar part extending in the first direction within the second multi-layered body, the second columnar part including a second memory film and a second semiconductor film, the second memory film including a charge storage part;
a first bit line on a side of the first multi-layered body opposite to the source line, the first bit line being electrically connected to the first columnar part; and
a second bit line on a side of the second multi-layered body opposite to the source line, the second bit line being electrically connected to the second columnar part.

2. The semiconductor storage device according to claim 1, wherein
the first columnar part and the second columnar part overlap each other when viewed from the first direction.

3. The semiconductor storage device according to claim 1, further comprising
a columnar body including the first columnar part and the second columnar part, wherein
the columnar body penetrates the first multi-layered body, the second multi-layered body, and the source line in the first direction.

4. The semiconductor storage device according to claim 3, wherein
the first memory film and the second memory film are separated from each other in the first direction,
the columnar body includes a semiconductor film,
the semiconductor film includes the first semiconductor film and the second semiconductor film, and
the semiconductor film is connected to the source line in a region between the first memory film and the second memory film.

5. The semiconductor storage device according to claim 1, wherein
the first semiconductor film and the second semiconductor film are separated from each other in the first direction, and
each of the first semiconductor film and the second semiconductor film is electrically connected to the source line.

6. The semiconductor storage device according to claim 1, wherein
the first columnar part has a first occupying part,
the first occupying part occupies more than half of a region configuring the first columnar part in the first direction,
the first columnar part has a first circumference in a cross-section intersecting the first direction in the first occupying part,
the first circumference increases in a direction from the first side toward a second side opposite to the first side, and wherein
the second columnar part has a second occupying part,
the second occupying part occupies more than half of a region configuring the second columnar part in the first direction,
the second columnar part has a second circumference in a cross-section intersecting the first direction in the second occupying part, and
the second circumference increases in a direction from the first side toward the second side.

7. The semiconductor storage device according to claim 1, wherein
the first columnar part includes a first end and a second end,
the first end is in contact with the source line,
the second end is on a side opposite to the first end,
the first columnar part has a first-end circumference at the second end and a second-end circumference at the second end,
the second-end circumference is greater than the first-end circumference, and wherein
the second columnar part includes a third end and a fourth end,
the third end is in contact with the source line,
the fourth end is on a side opposite to the third end,
the second columnar part has a third-end circumference at the third end and a fourth-end circumference at the fourth end, and
the fourth-end circumference is smaller than the third-end circumference.

8. The semiconductor storage device according to claim 1, further comprising:
a third columnar part extending in the first direction within the first multi-layered body, the third columnar part including a third memory film and a third semiconductor film, the third memory film including a charge storage part;
a fourth columnar part extending in the first direction within the second multi-layered body, the fourth columnar part including a fourth memory film and a fourth semiconductor film, the fourth memory film including a charge storage part; and
a conductive layer extending in the first direction, the conductive layer being connected to the source line, the conductive layer being at least either between the first columnar part and the third columnar part or between the second columnar part and the fourth columnar part.

9. The semiconductor storage device according to claim 1, wherein
a number of the first gate electrode layers included in the first multi-layered body is different from a number of the second gate electrode layers included in the second multi-layered body.

10. The semiconductor storage device according to claim 1, wherein
a number of the first gate electrode layers included in the first multi-layered body is the same as a number of the second gate electrode layers included in the second multi-layered body.

11. The semiconductor storage device according to claim 1, further comprising: p1 a sense amplifier module including a first terminal; and
a switching circuit configured to switch between a first state and a second state, wherein
the first terminal and the first bit line are electrically connected in the first state, and
the first terminal and the second bit line are electrically connected in the second state.

12. The semiconductor storage device according to claim 1, further comprising:
a fifth columnar part extending in the first direction within the first multi-layered body, the fifth columnar part including a fifth memory film and a fifth semiconductor film, the fifth memory film including a charge storage part;
a sixth columnar part extending in the first direction within the second multi-layered body, the sixth columnar part including a sixth memory film and a sixth semiconductor film, the sixth memory film including a charge storage part;
a circuit on a side of the first multi-layered body opposite to the second multi-layered body; and
contacts between the first columnar part and the fifth columnar part and between the second columnar part and the sixth columnar part, the contacts extending in the first direction, the contacts being electrically connects the circuit and the second bit line.

13. The semiconductor storage device according to claim 1, further comprising
a separation part including a first part and a second part, the first part separating each of the plurality of first gate electrode layers in the second direction, the second part separating each of the plurality of second gate electrode layers in the second direction, wherein
the separation part includes a conductive layer and an insulating film,
the insulating film covers the conductive layer, and
the conductive layer and the insulating film are over the first part and the second part,
a width of the first part in the second direction is larger than a width of the second part in the second direction,
a boundary between the first part and the second part is inside the source line,
the boundary has a step in the second direction,
the insulating film is separated in the second direction at the step,
the conductive layer is exposed to the outside of the insulating film, and
the conductive layer is connected to the source line.

14. A method of manufacturing a semiconductor storage device, the method comprising:
forming a first-stage multi-layered body, the first-stage multi-layered body including a plurality of first layers and a plurality of second layers, the plurality of first layers and the plurality of second layers being alternately stacked one by one in a first direction;
forming a third layer, the third layer extending in a direction intersecting the first direction above the first-stage multi-layered body;
forming a second-stage multi-layered body, the second-stage multi-layered body including a plurality of fourth layers and a plurality of fifth layers above the third layer, the plurality of fourth layers and the plurality of fifth layers being alternately stacked one by one in the first direction;
forming a first-stage columnar part, the first-stage columnar part extending in the first direction within the first-stage multi-layered body, the first-stage columnar part including a memory film and a semiconductor film, the memory film including a charge storage part;
forming a second-stage columnar part, the second-stage columnar part extending in the first direction within the second-stage multi-layered body, the second-stage columnar part including a memory film and a semiconductor film, the memory film including a charge storage part;
forming a bit line, the bit line being on a side of the second-stage columnar part opposite to the third layer, the bit line being electrically connected to the second-stage columnar part; and
forming a bit line, the bit line being on a side of the first-stage columnar part opposite to the third layer, the bit line being electrically connected to the first-stage columnar part.
